(19) United States
(12) Patent Application Publication
(10) Pub. No.: US 2024/0130437 A1
(43) Pub. Date: Apr. 25, 2024

(54) AEROSOL-GENERATING SYSTEM WITH DIELECTRIC HEATER

(71) Applicant: Philip Morris Products S.A., Neuchatel (CH)

(72) Inventors: Jerome Christian COURBAT, Cortaillod (CH); Robert William EMMETT, Neuchatel (CH); Ana Isabel GONZALEZ FLOREZ, St-Sulpice (CH); Roberto MANCINI, Bofflens (CH); Enrico TURRINI, Neuchatel (CH)

(73) Assignee: Philip Morris Products S.A., Neuchatel (CH)

(21) Appl. No.: 18/546,025

(22) PCT Filed: Feb. 15, 2022
(86) PCT No.: PCT/EP2022/053710

§ 371 Date: Aug. 9, 2023

(30) Foreign Application Priority Data
Feb. 16, 2021 (EP) 21157476.9

(51) Int. Cl. A24F 40/57; A24F 40/465; A24F 40/53; H05B 6/50

(52) U.S. Cl. CPC A24F 40/57; A24F 40/465; A24F 40/53; H05B 6/50

(57) ABSTRACT

An aerosol-generating system is provided, including: an aerosol-forming substrate; a first electrode and a second electrode spaced apart from the first electrode; an aerosol-generating device including a power supply, and a controller configured to connect to the first electrode and the second electrode; and a capacitor including the first electrode, the second electrode, and at least a portion of the aerosol-forming substrate, the controller being configured to supply an alternating voltage to the first electrode and the second electrode for dielectrically heating the aerosol-forming substrate, measure or determine an electrical property between the first electrode and the second electrode, and control heating of the aerosol-forming substrate based on the measured or determined electrical property.

The present disclosure relates to an aerosol-generating system, and an aerosol-generating device for generating an aerosol from an aerosol-forming substrate. In particular, this disclosure relates to an aerosol-generating system, and an aerosol-generating device for generating an aerosol for inhalation by a user.

There are many different types of personal vaporisers and heat-not-burn systems available that generate an inhalable aerosol from an aerosol-forming substrate. Some of these systems heat a liquid composition, others heat a solid tobacco mixture and some heat both a liquid composition and a solid substrate. Some available systems heat the aerosol-forming substrate by conduction of heat from a heating element to an aerosol-forming substrate. Most commonly this is achieved by passing an electrical current through an electrically resistive heating element, giving rise to Joule heating of the heating element. Inductive heating systems have also been proposed, in which Joule heating occurs as a result of eddy currents induced in a susceptor heating element.

One potential problem with these systems is that they can give rise to non-uniform heating of the aerosol-forming substrate. The portion of the aerosol-forming substrate closest to the heating element is heated more quickly or to a higher temperature than portions of the aerosol-forming substrate more remote from the heating element. To mitigate this problem, various designs have been used. Some designs use multiple heating elements to provide the ability to distribute heat or to heat different portions of the substrate at different times. Other designs transport only a small portion of the aerosol-forming substrate to a heating element so that only that small portion is vapourised, before transporting another portion of the aerosol-forming substrate to the heating element.

Systems that dielectrically heat an aerosol-forming substrate have been proposed, which advantageously provide uniform heating of the aerosol-forming substrate. However, it would be desirable to provide a system that dielectrically heats an aerosol-forming substrate in a manner that allows for greater heating control, while still being realisable in a compact handheld system.

According to the present disclosure, there is provided an aerosol-generating system. The aerosol-generating system may comprise an aerosol-forming substrate. The aerosol-generating system may comprise a first electrode, and a second electrode spaced apart from the first electrode. The aerosol-generating system may comprise an aerosol-generating device. The aerosol-generating device may comprise a power supply. The aerosol-generating device may comprise a controller. The controller may be configured to connect to the first electrode and the second electrode. The aerosol-generating system may include a capacitor comprising the first electrode and the second electrode. The capacitor may comprise at least a portion of the aerosol-forming substrate. The controller may be configured to supply an alternating voltage to the first electrode and the second electrode for dielectrically heating the aerosol-forming substrate. The controller may be configured to measure an electrical property between the first electrode and the second electrode. The controller may be configured to control heating of the aerosol-forming substrate based on the measured electrical property. The controller may be configured to determine an electrical property between the first electrode and the second electrode. The controller may be configured to control heating of the aerosol-forming substrate based on the determined electrical property.

The aerosol-generating system can give rise to dielectric heating of the aerosol-forming substrate. Dielectric heating can be uniform within a volume of aerosol-forming substrate, without the creation of hot spots. The heating also requires no contact between a heating element and the aerosol-forming substrate. This means that there is no need to clean a heating element that has a build-up of aerosol residue on it. The device allows for considerable design flexibility in terms of the shape, volume and composition of the aerosol-forming substrate and correspondingly the shape and volume of the substrate cavity.

The aerosol-generating system comprises a capacitor. The capacitor may comprise the first electrode and the second electrode. The capacitor may comprise the first electrode, the second electrode and at least a portion of the aerosol-forming substrate. The aerosol-forming substrate may be arranged between the first electrode and the second electrode. In some embodiments, only the aerosol-forming substrate is arranged between the first electrode and the second electrode. In other words, the aerosol-forming substrate may be arranged directly between the first electrode and the second electrode without any other intervening components. In some embodiments, the aerosol-forming substrate and one or more other components are arranged between the first electrode and the second electrode. In other words, the aerosol-forming substrate may be indirectly arranged between the first and second electrode, with one or more additional, intervening components arranged between at least one of the electrodes and the aerosol-forming substrate. For example, in some embodiments, the aerosol-generating system may comprise an aerosol-generating article comprising the aerosol-forming substrate and a wrapper circumscribing the aerosol-forming substrate. In these embodiments, at least a portion of the aerosol-generating article may be arranged between the first electrode and the second electrode. In these embodiments, at least a portion of the aerosol-forming substrate and at least a portion of the wrapper may be arranged between the first electrode and the second electrode. The controller may be configured to supply an alternating voltage to the capacitor.

The aerosol-forming substrate may comprise one or more dielectric material. The aerosol-forming substrate may be a dielectric material. The components arranged between the first electrode and the second electrode may comprise dielectric materials. The components arranged between the first electrode and the second electrode may be dielectric materials.

The controller of the aerosol-generating system is configured to measure or determine an electrical property between the first electrode and the second electrode. Measuring or determining an electrical property between the first electrode and the second electrode provides the controller with information about the materials arranged between the first electrode and the second electrode. When at least a portion of the aerosol-forming substrate is arranged between the first electrode and the second electrode, measuring or determining an electrical property between the first electrode and the second electrode comprises measuring or determining an electrical property of the aerosol-forming substrate. Advantageously, measuring or determining an electrical property of the aerosol-forming substrate enables the controller to control the heating of the aerosol-forming substrate based on the measured or determined electrical property of the aerosol-forming substrate. Such heating control may enable the controller to heat different aerosol-forming substrates to different temperatures. For example, the controller may be configured to heat different aerosol-forming substrates to different temperatures, wherein each aerosol-forming substrate is heated to the optimal temperature for aerosol-generation for that particular aerosol-forming substrate. Such heating control may also enable the controller to prevent heating of the aerosol-forming substrate when the measured or determined electrical property indicates that no aerosol-forming substrate is arranged between the first electrode and the second electrode, or the aerosol-forming substrate arranged between the first electrode and the second electrode is not suitable for use with the aerosol-generating device.

Particularly advantageously, the system of the disclosure uses one pair of electrodes to both dielectrically heat an aerosol-forming substrate, and to measure an electrical property of the aerosol-forming substrate. By using the same pair of electrodes to heat the aerosol-forming substrate and measure a property of the aerosol-forming substrate, the system of the disclosure reduces the number of components required by the system, which may reduce the size and weight of the aerosol-generating system, and may also reduce the manufacturing complexity of the aerosol-generating system.

In the system of the present disclosure, the first electrode and the second electrode may be arranged in any suitable manner. In some embodiments, the aerosol-generating device comprises the first electrode and the second electrode. In some embodiments, the aerosol-generating system comprises an aerosol-generating article comprising the aerosol-forming substrate, and the aerosol-generating article further comprises the first electrode and the second electrode. In some embodiments, the aerosol-generating system comprises an aerosol-generating article comprising the aerosol-forming substrate, the aerosol-generating device comprises one of the first electrode and the second electrode, and the aerosol-generating article comprises the other one of the first electrode and the second electrode.

As used herein, the term “aerosol-forming substrate” relates to a substrate capable of releasing volatile compounds that can form an aerosol. Such volatile compounds may be released by heating the aerosol-forming substrate. An aerosol-forming substrate is typically part of an aerosol-generating article.

As used herein, the term “aerosol-generating article” refers to an article comprising an aerosol-forming substrate that is capable of releasing volatile compounds that can form an aerosol. For example, an aerosol-generating article may be an article that generates an aerosol that is directly inhalable by the user drawing or puffing on a mouthpiece. An aerosol-generating article may be disposable. An article comprising an aerosol-forming substrate comprising tobacco may be referred to as a tobacco stick.

As used herein, the term “aerosol-generating device” refers to a device that interacts with an aerosol-forming substrate to generate an aerosol. An aerosol-generating article is separate from and configured for combination with an aerosol-generating device for heating the aerosol-generating article.

As used herein, the term “aerosol-generating system” refers to the combination of an aerosol-generating device with an aerosol-forming substrate. In the aerosol-generating system, the aerosol-forming substrate and the aerosol-generating device cooperate to generate an aerosol.

According to the present disclosure, there is provided an aerosol-generating device for dielectrically heating an aerosol-forming substrate. The aerosol-generating device may comprise a first electrode and a second electrode spaced apart from the first electrode. The aerosol-generating device may comprise a power supply. The aerosol-generating device may comprise a controller configured to connect to the first electrode and the second electrode. The first electrode and the second electrode may be configured to form a capacitor. The first electrode and the second electrode may be configured to form a capacitor with a portion of the aerosol-forming substrate to be dielectrically heated. The controller may be configured to supply an alternating voltage to the first electrode and the second electrode for dielectrically heating a portion of the aerosol-forming substrate. The controller may be configured to measure an electrical property between the first electrode and the second electrode. The controller may be configured to control heating of the aerosol-forming substrate based on the measured electrical property. The controller may be configured to determine an electrical property between the first electrode and the second electrode. The controller may be configured to control heating of the aerosol-forming substrate based on the determined electrical property.

The controller controls the heating of the aerosol-forming substrate based on the measured or determined electrical property between the first electrode and the second electrode. The controller may control the heating of the aerosol-forming substrate in any suitable manner. In some preferred embodiments, the controller may control the heating of the aerosol-forming substrate by controlling the alternating voltage supplied to the first electrode and the second electrode to control heating of the aerosol-forming substrate based on the measured or determined electrical property. The controller may be configured to control the alternating voltage supplied to the first electrode and the second electrode to control the heating of the aerosol-forming substrate based on the measured or determined electrical property. The control circuitry may be configured to adjust the frequency of the alternating voltage to control the heating of the aerosol-forming substrate. The control circuitry may be configured to adjust the amplitude of the alternating voltage to control the heating of the aerosol-forming substrate. The control circuitry may be configured to adjust the amplitude and the frequency of the alternating voltage to control the heating of the aerosol-forming substrate.

The controller is configured to measure or determine an electrical property between the first electrode and the second electrode. The electrical property may be any suitable electrical property. In some embodiments, the electrical property is the capacitance between the first electrode and the second electrode. The electrical property may be the capacitance of the capacitor comprising the first electrode, the second electrode and at least a portion of the aerosol-forming substrate. In some preferred embodiments, the electrical property is the impedance between the first electrode and the second electrode. The electrical property may be the impedance of the capacitor comprising the first electrode, the second electrode and at least a portion of the aerosol-forming substrate.

The controller may measure or determine the electrical property between the first electrode and the second electrode in any suitable manner.

In some embodiments, the controller is configured to supply an alternating voltage to the first electrode and the second electrode for measuring or determining the electrical property between the first electrode and the second electrode. Supplying an alternating voltage to the first electrode and the second electrode for measuring or determining the electrical property between the first electrode and the second electrode may enable the controller to measure or determine the impedance between the first electrode and the second electrode.

In some embodiments, the controller is configured to measure an alternating electrical current supplied to the first electrode and the second electrode when the alternating voltage for measuring or determining the electrical property between the first electrode and the second electrode is supplied.

The controller may be configured to measure an alternating electrical current supplied to the first electrode and the second electrode when the alternating voltage for measuring or determining the electrical property between the first electrode and the second electrode is supplied. In some embodiments, the controller may be configured to control heating of a portion of the aerosol-forming substrate based on the measured alternating current. In some embodiments, the controller may be configured to determine the impedance between the first electrode and the second electrode based on the measured alternating current. The controller may be configured to control heating of the aerosol-forming substrate based on the determined impedance. Advantageously, measuring the alternating current supplied to the first electrode and the second electrode may provide a precise indication of the electrical property, such as the impedance or capacitance, between the first electrode and the second electrode.

The frequency of the alternating voltage supplied to the first electrode and the second electrode for measuring or determining the electrical property between the first electrode and the second electrode may be between about 10 hertz and about 100 gigahertz. Preferably, the frequency of the alternating voltage supplied to the first electrode and the second electrode for measuring or determining the electrical property between the first electrode and the second electrode is between about 10 kilohertz, and about 100 megahertz. More preferably, the frequency of the alternating voltage supplied to the first electrode and the second electrode for measuring or determining the electrical property between the first electrode and the second electrode is between about 1 megahertz, and about 300 megahertz. In some embodiments, the frequency of the alternating voltage supplied to the first electrode and the second electrode for measuring or determining the electrical property between the first electrode and the second electrode is between about 1 kilohertz, and about 1 megahertz. In some embodiments, the frequency of the alternating voltage supplied to the first electrode and the second electrode for measuring or determining the electrical property between the first electrode and the second electrode is between about 1 megahertz and about 100 megahertz.

The frequency of the alternating voltage supplied to the first electrode and the second electrode for heating the aerosol-forming substrate may be between about 3 hertz and 3 terahertz. As used herein, radio frequency (RF) means a frequency between 3 hertz and 3 terahertz, and includes microwaves. Preferably, the frequency of the alternating voltage supplied to the first electrode and the second electrode for heating the aerosol-forming substrate is between 10 hertz and about 100 gigahertz, more preferably between about 10 kilohertz, and about 500 megahertz, and more preferably between about 1 megahertz, and about 300 megahertz. The frequency of the alternating voltage supplied to the first electrode and the second electrode for heating the aerosol-forming substrate may be between 1 megahertz, and 300 megahertz.

In preferred embodiments, the frequency of the alternating voltage supplied to the first electrode and the second electrode for measuring or determining the electrical property between the first electrode and the second electrode is the same as the frequency of the alternating voltage supplied to the first electrode and the second electrode for heating the aerosol-forming substrate. Advantageously, supplying alternating voltages at the same frequency for measuring or detecting an electrical property between the first and second electrodes, and for heating the aerosol-forming substrate enables the same electronic circuit to be used for both purposes.

In some preferred embodiments, the power supply is configured to supply a direct voltage. In these preferred embodiments, a DC/AC converter may be arranged at an output of the power supply for supplying an alternating voltage to the first electrode and the second electrode. The controller may be configured to control the supply of the alternating voltage from the DC/AC converter to the first electrode and the second electrode. The controller may be configured to control the supply of the alternating voltage from the DC/AC converter to the first electrode and the second electrode for dielectrically heating the aerosol-forming substrate. The controller may be configured to control the supply of the alternating voltage from the DC/AC converter to the first electrode and the second electrode for measuring or determining the electrical property between the first electrode and the second electrode.

In some particularly preferred embodiments, the controller is configured to measure the direct electrical current supplied to the DC/AC converter. In some of these embodiments, the controller may be configured to control heating of the aerosol-forming substrate based on the measured direct current. In some of these embodiments, the controller is configured to determine the impedance between the first electrode and the second electrode based on the measured direct current. The controller may be configured to control heating of the aerosol-forming substrate based on the determined impedance. Advantageously, measuring the direct electrical current supplied to the DC/AC converter may minimise the complexity and cost of the aerosol-generating system, and maximise the robustness of the system, since measuring a direct current may be achieved using well known techniques and uncomplicated arrangements of electrical components.

In some embodiments, a portion of the aerosol-forming substrate is removably receivable between the first electrode and the second electrode. In these embodiments, the controller may be configured to determine whether aerosol-forming substrate is received between the first electrode and the second electrode based on the measured or determined electrical property between the first electrode and the second electrode. In some preferred embodiments, the controller is configured to prevent heating of the aerosol-forming substrate when it is determined that aerosol-forming substrate is not received between the first electrode and the second electrode. The controller may be configured to prevent the supply of the alternating voltage to the first electrode and the second electrode for dielectrically heating a portion of the aerosol-forming substrate. Advantageously, preventing heating of the aerosol-forming substrate when it is determined that aerosol-forming substrate is not received between the first electrode and the second electrode may reduce the power consumption of the aerosol-generating system by ensuring that the alternating current for heating the aerosol-forming substrate is not supplied to the first and second electrode when aerosol-forming substrate is not arranged between the first electrode and the second electrode.

In some embodiments, the controller is configured to determine the temperature of the aerosol-forming substrate based on the measured or determined electrical property between the first electrode and the second electrode. The controller may be configured to determine the temperature of the aerosol-forming substrate arranged between the first electrode and the second electrode.

The inventors of the present disclosure have realised that some electrical properties of the aerosol-forming substrate are dependent on the temperature of the aerosol-forming substrate. Accordingly, measuring or detecting an electrical property between the first electrode and the second electrode may provide an indication of the temperature of the aerosol-forming substrate. Advantageously, determining the temperature of the aerosol-forming substrate may enable the controller to provide improved control of the heating of the aerosol-forming substrate.

According to the disclosure there is provided an aerosol-generating system comprising an aerosol-forming substrate; a first electrode and a second electrode spaced apart from the first electrode; and an aerosol-generating device comprising: a power supply; and a controller configured to connect to the first electrode and the second electrode. The system includes a capacitor comprising the first electrode, the second electrode, and at least a portion of the aerosol-forming substrate. The controller is configured to: measure or determine an electrical property between the first electrode and the second electrode; and determine the temperature of the aerosol-forming substrate based on the measured or determined electrical property. In other words, there is provided an aerosol-generating system having a controller that is configured to determine the temperature of the aerosol-forming substrate based on a measured or determined electrical property between a first electrode and a second electrode, and which may not be configured to dielectrically heat the aerosol-forming substrate. It will also be appreciated that in some embodiments the controller is further configured to supply an alternating voltage to the first electrode and the second electrode for heating the aerosol-forming substrate.

According to the disclosure there is also provided an aerosol-generating device comprising: a power supply; a first electrode and a second electrode, and a controller configured to connect to the first electrode and the second electrode. The system includes a capacitor comprising the first electrode, the second electrode, and at least a portion of the aerosol-forming substrate. The controller is configured to: measure or determine an electrical property between the first electrode and the second electrode; and determine the temperature of the aerosol-forming substrate based on the measured or determined electrical property.

In some embodiments, the controller is configured to determine a physical characteristic of the aerosol-forming substrate based on the measured or determined electrical property. For example, the controller may be configured to determine the composition of the aerosol-forming substrate based on the measured or determined electrical property. Accordingly, the controller may be configured to heat aerosol-forming substrates with different compositions to different temperatures. Advantageously, this may enable the aerosol-generating to heat multiple aerosol-forming substrates to the optimal temperature for generation of aerosol for that particular aerosol-forming substrate composition.

In some embodiments in which the aerosol-forming substrate is removably receivable between the first electrode and the second electrode, the controller is configured to determine whether the aerosol-forming substrate received between the first electrode and the second electrode is authentic based on the measured or determined electrical property. In some preferred embodiments the controller is configured to prevent heating of the aerosol-forming substrate when it is determined that the aerosol-forming substrate received between the first electrode and the second electrode is not authentic. Advantageously, preventing heating of the aerosol-forming substrate when it is determined that the aerosol-forming substrate received between the first electrode and the second electrode is not authentic may enable the aerosol-generating system to prevent heating of an unauthorised aerosol-forming substrate that may generate an unacceptable or undesirable aerosol.

In some embodiments, the system comprises a resonant circuit, having a resonant frequency. The resonant circuit may comprise the first electrode, the second electrode, and at least a portion of the aerosol-forming substrate. The resonant frequency may be dependent on the electrical property between the first electrode and the second electrode.

In some embodiments, the system comprises an inductor. Preferably, the inductor is arranged between the power supply, and the capacitor comprising the first electrode, the second electrode and at least a portion of the aerosol-forming substrate. The inductor may be arranged directly between the power supply and the capacitor, such that no other intervening components are provided between the inductor and the power supply, and the inductor and the capacitor. The inductor may be arranged indirectly between the power supply and the capacitor, such that one or more intervening components are provided between the inductor and the power supply, and the inductor and the capacitor. The inductor and the capacitor comprising the first electrode, the second electrode and at least a portion of the aerosol-forming substrate may form a resonant circuit having a resonant frequency. The resonant frequency may be dependent on the measured or determined electrical property between the first electrode and the second electrode.

The controller may be configured to supply the alternating voltage to the first electrode and the second electrode for heating the aerosol-forming substrate at the resonant frequency of the resonant circuit. Advantageously, supplying the alternating voltage to the first electrode and the second electrode for heating the aerosol-forming substrate at the resonant frequency of the resonant circuit may increase the efficiency of the heating of the aerosol-forming substrate. In other words, supplying the alternating voltage to the first electrode and the second electrode for heating the aerosol-forming substrate at the resonant frequency of the resonant circuit may require less power to be supplied to the first electrode and the second electrode in order to heat the aerosol-forming substrate to the desired temperature for aerosol generation.

In some embodiments, the controller may be configured to determine the resonant frequency of the resonant circuit based on the measured or detected electrical property. In some embodiments, the controller may be configured to determine whether the resonant circuit is being supplied with an alternating voltage at the resonant frequency of the resonant circuit. In particular, the controller may be configured to supply an alternating voltage to the first electrode and the second electrode at a detection frequency. The controller may be further configured to determine whether the detection frequency is the resonant frequency of the resonant circuit based on the measured or determined electrical property. The measured or determined electrical property between the first electrode and the second electrode may fluctuate at the resonant frequency of the resonant circuit, for example the impedance between the first electrode and the second electrode may be lower at the resonant frequency than at other frequencies close to the resonant frequency. Accordingly, the controller may be configured to determine a fluctuation of the measured or determined electrical property at the resonant frequency.

In embodiments where the controller is configured to determine whether the detection frequency is the resonant frequency of the resonant circuit, the controller may be configured to determine whether the aerosol-forming substrate is authentic based on the determined resonant frequency.

According to this disclosure there is provided an aerosol-generating system comprising: an aerosol-forming substrate; a first electrode and a second electrode spaced apart from the first electrode; and an aerosol-generating device comprising: a power supply; and a controller configured to connect to the first electrode and the second electrode. The system comprises a resonant circuit comprising the first electrode, the second electrode, and at least a portion of the aerosol-forming substrate, the resonant circuit having a resonant frequency. The controller may be configured to determine the resonant frequency of the resonant circuit based on the measured or determined electrical property between the first electrode and the second electrode. The controller may be configured to determine whether the resonant circuit is being supplied with an alternating voltage at the resonant frequency of the resonant circuit based on the measured or determined electrical property between the first electrode and the second electrode. In other words, there is provided an aerosol-generating system having a controller that is configured to determine the resonant frequency of the resonant circuit, or determine whether the resonant circuit is being supplied with an alternating voltage at the resonant frequency of the resonant circuit, based on a measured or determined electrical property between a first electrode and a second electrode, and which may not be configured to dielectrically heat the aerosol-forming substrate. It will also be appreciated that in some embodiments the controller is further configured to supply an alternating voltage to the first electrode and the second electrode for heating the aerosol-forming substrate. In these embodiments, the controller may be configured to supply an alternating voltage to the first electrode and the second electrode for heating the aerosol-forming substrate at a frequency dependent on the determined resonant frequency of the resonant circuit.

In some embodiments, the controller is configured to determine whether the aerosol-forming substrate is authentic based on the determined resonant frequency. The controller may be configured to supply an alternating voltage to the resonant circuit at a detection frequency, and the controller may be further configured to determine that the aerosol-forming substrate is authentic when it is determined that the detection frequency is the resonant frequency of the resonant circuit.

In some preferred embodiments, the controller is configured to supply a first alternating voltage to the first electrode and the second electrode for measuring or determining the electrical property between the first electrode and the second electrode at a first frequency, and to supply a second alternating voltage to the first electrode and the second electrode for measuring or determining the electrical property between the first electrode and the second electrode at a second frequency, different to the first frequency. The controller may be configured to measure or determine the impedance between the first electrode and the second electrode based on the measured alternating current for each of the first alternating voltage and the second alternating voltage. The controller may be configured to control the heating of the aerosol-forming substrate based on the measured or determined impedance for both the first alternating voltage and the second alternating voltage. The controller may be configured to determine the composition, or the authenticity of the aerosol-forming substrate based on the measured or determined impedance for both the first alternating voltage and the second alternating voltage. The controller may be configured to determine the temperature of the aerosol-forming substrate based on the measured or determined impedance for both the first alternating voltage and the second alternating voltage. Measuring or determining the electrical property using alternating voltages at a plurality of different frequencies may provide a more robust determination of one or more of the electrical property, the composition or authenticity of the aerosol-forming substrate, and the temperature of the aerosol-forming substrate.

The controller may be configured to supply alternating voltages to the first electrode and the second electrode for measuring or determining the electrical property between the first electrode and the second electrode at a plurality of frequencies.

In some embodiments, the aerosol-generating device comprises an oscillation circuit. The oscillation circuit may be arranged between the controller and the capacitor comprising the first electrode, the second electrode and at least a portion of the aerosol-forming substrate. In some embodiments, the oscillation circuit is arranged directly between the controller and the capacitor, such that no other intervening electrical components are provided between the controller and the oscillation circuit and the capacitor and the oscillation circuit. In some embodiments, the oscillation circuit is arranged indirectly between the controller and the capacitor, such that one or more intervening electrical components are provided between the controller and the oscillation circuit and the capacitor and the oscillation circuit.

The oscillation circuit may be configured to supply the alternating voltage to the first electrode and the second electrode for heating the aerosol-forming substrate. The controller may be configured to control the oscillation circuit to supply the alternating voltage to the first electrode and the second electrode for heating the aerosol-forming substrate.

In some embodiments where the aerosol-generating device comprises a DC/AC converter, the oscillation circuit may comprise the DC/AC converter.

In some embodiments where the aerosol-generating device comprises a DC/AC converter, the DC/AC converter may supply an alternating voltage to the oscillation circuit. The DC/AC converter may be arranged between the power supply and the oscillation circuit. The oscillation circuit may be arranged between the DC/AC converter and the capacitor comprising the first electrode, the second electrode and at least a portion of the aerosol-forming substrate.

The oscillation circuit may comprise a radio frequency (RF) signal generator. The RF signal generator may be any suitable type of RF signal generator. In some embodiments, the RF signal generator is a solid state RF transistor. Advantageously, a solid state RF transistor may be configured to generate and amplify the RF electromagnetic field. Using a single transistor to provide both the generating and amplification of the RF electromagnetic field allows for a shish device to be compact. The solid state RF transistor may be, for example, a LDMOS transistor, a GaAs FET, a SiC MESFET or a GaN HFET.

In some embodiments, the oscillation circuit may further comprise a frequency synthesizer disposed between the RF signal generator and the first electrode and the second electrode.

In some embodiments, the oscillation circuit may further comprise a phase shift network disposed between the RF signal generator and the first electrode and the second electrode. Where the oscillation circuit comprises a phase shift network, the phase shift network divides the RF energy received from the RF signal generator into two separate, equal components that are out of phase with each other. Typically, the phase shift network supplies one of the components to the first electrode, and supplies the other component to the second electrode. The two substantially equal components of the RF energy received from the RF signal generator are preferably substantially 90 degrees or 180 degrees out of phase with each other. The two substantially equal components may be any multiple of 90 degrees or 180 degrees out of phase with each other. It will be appreciated that the precise phase relationship between the two components is not essential, but rather that the two components are not in phase.

In some embodiments, the phase network is configured to divide the RF energy from the RF signal generator into two substantially equal components, one out of phase with the other, and each component is applied to a different one of the first electrode and the second electrode. In some of these embodiments, the first electrode and the second electrode may be arranged opposite and facing each other. In some of these embodiments, the first electrode and the second electrode are arranged side by side, spaced apart from and facing an opposing third electrode, that is connected to ground.

The first electrode and the second electrode may take any suitable form. In some embodiments, the first electrode is substantially identical to the second electrode. In some embodiments, the first electrode is different to the second electrode.

In some preferred embodiments, the first electrode and the second electrode are planar electrodes. The first planar electrode may extend substantially in a first plane. The second planar electrode may extend substantially in a second plane. Preferably, the first plane is substantially parallel to the second plane. Preferably, the second planar electrode is substantially identical to the first planar electrode.

In some preferred embodiments, the first electrode circumscribes the second electrode. Where the aerosol-forming substrate is removably receivable between the first electrode and the second electrode, the first electrode may circumscribe the second electrode when the aerosol-generating substrate is received between the first electrode and the second electrode.

The first electrode may be an annular electrode comprising an inner cavity. The second electrode may be received in the inner cavity of the first electrode. The aerosol-forming substrate may be received in the inner cavity of the first electrode. Where the aerosol-forming substrate is removably receivable between the first electrode and the second electrode, the aerosol-forming substrate may be received in the inner cavity of the first electrode when the aerosol-forming substrate is received between the first electrode and the second electrode.

The first electrode and the second electrode may be formed from an electrically conductive material. As used herein, “electrically conductive” means formed from a material having a resistivity of 1×10⁻⁴ Ohm meter, or less. As used herein, “electrically insulating” means formed from a material having a resistivity of 1×10⁴ Ohm meter or more.

The aerosol-generating device comprises a controller. The controller may comprise a microprocessor, a programmable microprocessor, a microcontroller, or an application specific integrated chip (ASIC) or other electronic circuitry capable of providing control. The controller may comprise further electronic components. For example, in some embodiments, the controller may comprise any of: sensors, switches, display elements. The controller may comprise an RF power sensor. The controller may comprise a power amplifier.

The aerosol-generating device comprises a power supply. The power supply may be a DC power supply. The power supply may comprise at least one battery. The at least one battery may include a rechargeable lithium ion battery. As an alternative, the power supply may be another form of charge storage device, such as a capacitor. The power supply may provide a power of between 0.5 Watts and 60 Watts, or preferably between 20 Watts and 40 Watts.

The aerosol-generating device may comprise a puff detector configured to detect when a user takes a puff on the aerosol-generating system. As used herein, the term “puff” is used to refer to a user drawing on the aerosol-generating system to receive aerosol. Where the aerosol-generating device comprises a puff detector, the controller may be configured to supply the alternating voltage to the first electrode and the second electrode for heating the aerosol-forming substrate when a puff is detected by the puff detector.

Preferably, the aerosol-generating device is portable. The aerosol-generating device may have a size comparable to a conventional cigar or cigarette. The aerosol-generating device may have a total length between about 30 millimetres and about 150 millimetres. The aerosol-generating device may have an outer diameter between about 5 millimetres and about 30 millimetres. The substrate cavity may have a diameter between 2 millimetres and 20 millimetres. The substrate cavity may have a length between 2 millimetres and 20 millimetres. The aerosol-generating device may be a personal vaporiser, an e-cigarette or heat-not-burn device.

The aerosol-generating system comprises an aerosol-forming substrate. The aerosol-forming substrate may comprise a solid. The aerosol-forming substrate may comprise a liquid. The aerosol-forming substrate may comprise a gel. The aerosol-forming substrate may comprise any combination of two or more of a solid, a liquid and a gel.

The aerosol-forming substrate may comprise nicotine, a nicotine derivative or a nicotine analogue. The aerosol-forming substrate may comprise one or more nicotine salt. The one or more nicotine salt may be selected from the list consisting of nicotine citrate, nicotine lactate, nicotine pyruvate, nicotine bitartrate, nicotine pectates, nicotine aginates, and nicotine salicylate.

The aerosol-forming substrate may comprise an aerosol former. As used herein, an “aerosol former” is any suitable known compound or mixture of compounds that, in use, facilitates formation of a dense and stable aerosol and that is substantially resistant to thermal degradation at the operating temperature of the aerosol-generating article. Suitable aerosol-formers are well known in the art and include, but are not limited to: polyhydric alcohols, such as triethylene glycol, 1,3-butanediol and glycerine; esters of polyhydric alcohols, such as glycerol mono-, di- or triacetate; and aliphatic esters of mono-, di- or polycarboxylic acids, such as dimethyl dodecanedioate and dimethyl tetradecanedioate. Preferred aerosol formers are polyhydric alcohols or mixtures thereof, such as triethylene glycol, 1,3-butanediol and glycerine.

The aerosol-forming substrate may further comprise a flavourant. The flavourant may comprise a volatile flavour component. The flavourant may comprise menthol. As used herein, the term ‘menthol’ denotes the compound 2-isopropyl-5-methylcyclohexanol in any of its isomeric forms. The flavourant may provide a flavour selected from the group consisting of menthol, lemon, vanilla, orange, wintergreen, cherry, and cinnamon. The flavourant may comprise volatile tobacco flavour compounds which are released from the substrate upon heating.

The aerosol-forming substrate may further comprise tobacco or a tobacco containing material. For example, the aerosol-forming substrate may comprise any of: tobacco leaf, fragments of tobacco ribs, reconstituted tobacco, homogenised tobacco, extruded tobacco, tobacco slurry, cast leaf tobacco and expanded tobacco. Optionally, the aerosol-forming substrate may comprise tobacco powder compressed with an inert material, for example, glass or ceramic or another suitable inert material.

In some examples, the aerosol-forming substrate includes one or more sensory-enhancing agents. Suitable sensory-enhancing agents include flavourants and sensation agents, such as cooling agents. Suitable flavourants include natural or synthetic menthol, peppermint, spearmint, coffee, tea, spices (such as cinnamon, clove, ginger, or combination thereof), cocoa, vanilla, fruit flavours, chocolate, eucalyptus, geranium, eugenol, agave, juniper, anethole, linalool, and any combination thereof.

In cases where the aerosol-forming substrate comprises a liquid or a gel, in some embodiments, the aerosol-generating article may comprise an absorbent carrier. The aerosol-forming substrate may be coated on or impregnated into the absorbent carrier. For example, the nicotine compound and the aerosol-former may be combined with water as a liquid formulation. The liquid formulation may, in some embodiments, further comprise a flavourant. Such a liquid formulation may then be absorbed by the absorbent carrier or coated onto the surface of the absorbent carrier. The absorbent carrier may be a sheet or tablet of cellulosic-based material onto which the nicotine compound and the aerosol former may be coated or absorbed. The absorbent carrier may be a metallic, polymer or vegetal foam having liquid retaining and capillary properties and onto which the liquid or gel aerosol-forming substrate is coated or absorbed.

The aerosol-forming substrate may comprise a liquid filled capsule. The aerosol-forming substrate may comprise a gel filled capsule. The liquid filled capsule or the gel filled capsule may be configured to rupture when the liquid or gel is heated. The liquid filled capsule or the gel filled capsule may comprise one or more valves. The one or more valves may be configured to open when the liquid or gel is heated owing to an increase in pressure within the capsule. The one or more valves may be configured to open when a user draws air through the aerosol-generating system.

In some preferred embodiments, the aerosol-generating system comprises an aerosol-generating article comprising the aerosol-forming substrate. The aerosol-generating article may be separate from the aerosol-generating device. The aerosol-generating article may be removably receivable by the aerosol-generating device. The aerosol-generating device may be configured to receive at least a portion of the aerosol-generating article. The aerosol-generating device may be configured to receive the aerosol-generating article. The aerosol-generating device may comprise an article cavity configured to receive at least a portion of the aerosol-generating article.

The aerosol-generating article may comprise a wrapper circumscribing the aerosol-forming substrate. The wrapper may comprise an electrically insulative material. For example, the wrapper may comprise cigarette paper.

The aerosol-generating article may comprise a mouthpiece. The aerosol-generating article may comprise a filter in the mouthpiece. The aerosol-generating article may comprise a cooling element. The aerosol-generating article may comprise a spacing element.

The aerosol-generating article may comprise the aerosol-forming substrate at an upstream end, and a mouthpiece at a downstream end. The aerosol-forming substrate and the mouthpiece may be secured together by a wrapper circumscribing the aerosol-forming substrate and the mouthpiece. The aerosol-forming substrate and the mouthpiece may be arranged end to end in the form of a rod. Optionally, at least one of a cooling element, and a spacing, may be arranged between the aerosol-forming substrate and the mouthpiece.

In some embodiments, the aerosol-generating system may be a shisha system. In some embodiments, the aerosol-generating device may be a shisha device. Shisha devices are different to other aerosol-generating devices, at least in that volatile compounds released from a heated substrate are drawn through a liquid basin of the shisha device before inhalation by a user. A shisha device may include more than one outlet so that the device may be used by more than one user at a time. A shisha device may comprise an airflow conduit, such as a stem pipe, for directing volatile compounds released from the aerosol-forming substrate to the liquid basin.

As used herein, the term “shisha system” refers to the combination of a shisha device with an aerosol-forming substrate or with an aerosol-generating article comprising an aerosol-forming substrate. In the shisha system, the aerosol-forming substrate or an aerosol-generating article comprising the aerosol-forming substrate and the shisha device cooperate to generate an aerosol.

A shisha device differs from other aerosol-generating devices in that the aerosol generated by a shisha device is drawn through a volume of liquid, typically water, before inhalation of the aerosol by a user. In more detail, when a user draws on a shisha device, volatile compounds released from a heated aerosol-forming substrate are drawn through an airflow conduit of the shisha device into a volume of liquid. The volatile compounds are drawn out of the volume of liquid into a headspace of the shisha device, in which the volatile compounds form an aerosol. The aerosol in the headspace is then drawn out of the headspace at a headspace outlet for inhalation by a user. The volume of liquid, typically water, acts to reduce the temperature of the volatile compounds, and may impart additional water content to the aerosol formed in the headspace of the shisha device. This process adds distinctive characteristics to the process of using a shisha device for a user, and imparts distinctive characteristics to the aerosol generated by the shisha device and inhaled by a user.

The shisha device may comprise a liquid cavity configured to contain a volume of liquid. The liquid cavity may comprise a head space outlet. The shisha device may include a vessel. The liquid cavity may be an interior volume of a vessel. The vessel may be configured to contain a liquid. The vessel may define the liquid cavity. The vessel may comprise the headspace outlet. The vessel may define a liquid fill level. For example, the vessel may comprise a liquid fill level demarcation. A liquid fill level demarcation is an indicator provided on the vessel to indicate the desired level to which the liquid cavity is intended to be filled with liquid. The headspace outlet may be arranged above the liquid fill level. The headspace outlet may be arranged above the liquid fill level demarcation. The vessel may comprise an optically transparent portion. The optically transparent portion may enable a user to observe the contents contained in the vessel. The vessel may be formed from any suitable material. For example, the vessel may be formed from glass or a rigid plastic material. In some embodiments, the vessel is removable from the rest of the shisha assembly. In some embodiments, the vessel is removable from an aerosol-generating portion of the shisha assembly. Advantageously, a removable vessel enables a user to fill the liquid cavity with liquid, empty the liquid cavity of liquid, and clean the vessel.

The vessel may be filled to a liquid fill level by a user. The liquid preferably comprises water. The liquid may comprise water infused with one or more of colorants and flavourants. For example, the water may be infused with one or both of botanical and herbal infusions.

The vessel may have any suitable shape and size. The liquid cavity may have any suitable shape and size. The headspace may have any suitable shape and size.

Typically, a shisha device according to this disclosure is intended to be placed on a surface in use, rather than being carried by a user. As such, a shisha device according to this disclosure may have a particular use orientation, or range of orientations, at which the device is intended to be oriented during use. Accordingly, as used herein, the terms ‘above’ and ‘below’ refer to relative positions of features of a shisha device or a shisha system when the shisha device or shisha system is held in a use orientation.

The shisha device may comprise an article cavity for receiving an aerosol-generating article. In some embodiments, the article cavity is arranged above the liquid cavity. In these embodiments, an airflow conduit may extend from the article cavity to below a liquid fill level of the liquid cavity. Advantageously, this may ensure that volatile compounds released from aerosol-forming substrate in the article cavity are delivered from the article cavity to the volume of liquid in the liquid cavity, rather than to the headspace above the liquid cavity. In these embodiments, the airflow conduit may extend from the aerosol cavity into the liquid cavity through the headspace in the liquid cavity above the liquid fill level, and into the volume of liquid below the liquid fill level. The airflow conduit may extend into the liquid cavity through a top or upper end of the liquid cavity.

In some embodiments, the article cavity is arranged below the liquid cavity. In these embodiments, a one-way valve may be arranged between the article cavity and the liquid cavity. The one-way valve may prevent liquid from the liquid cavity from entering the article cavity under the influence of gravity. In these embodiments, the one-way valve may be provided in an airflow conduit extending from the article cavity into the liquid cavity. In these embodiments, the airflow conduit may extend into the liquid cavity to below the liquid fill level. The airflow conduit may extend into the liquid cavity through a bottom end of the liquid cavity.

The aerosol-forming substrate may be a shisha aerosol-forming substrate. A shisha aerosol-forming substrate may also be referred to in the art as hookah tobacco, tobacco molasses, or simply as molasses. A shisha aerosol-forming substrate may be relatively high in sugar, compared to conventional combustible cigarettes or tobacco based consumable items intended to be heated without burning to simulate a smoking experience.

In some preferred embodiments, the aerosol-forming substrate is in the form of a suspension. For example, the aerosol-forming substrate may include molasses. As used herein, “molasses” means an aerosol-forming substrate composition comprising a suspension having at least about 20 percent by weight of sugar. For example, the molasses may include at least about 25 percent by weight of sugar, such as at least about 35 percent by weight of sugar. Typically, the molasses will contain less than about 60 percent by weight of sugar, such as less than about 50 percent by weight of sugar.

Preferably, the aerosol-forming substrate used in the shisha system is a shisha substrate. As used herein, a “shisha substrate” refers to an aerosol-forming substrate composition comprising at least about 20 percent by weight of sugar. A shisha substrate may comprise molasses. A shisha substrate may comprise a suspension having at least about 20 percent by weight of sugar.

The aerosol-forming substrate preferably includes nicotine and at least one aerosol former. In some embodiments, the aerosol former is glycerine or a mixture of glycerine and one or more other suitable aerosol formers, such as those listed above. In some embodiments, the aerosol-forming is propylene glycol.

The aerosol-forming substrate may include other additives and ingredients, such as flavourants. In some examples, the aerosol-forming substrate includes one or more sugars in any suitable amount. Preferably, the aerosol-forming substrate includes invert sugar. Invert sugar is a mixture of glucose and fructose obtained by splitting sucrose. Preferably, the aerosol-forming substrate includes between about 1 percent and about 40 percent sugar, such as invert sugar, by weight. In some example, one or more sugars may be mixed with a suitable carrier such as cornstarch or maltodextrin.

Any suitable amount of aerosol-forming substrate, such as molasses or tobacco substrate, may be provided in the aerosol-generating article. In some preferred embodiments, about 3 grams to about 25 grams of the aerosol-forming substrate is provided in the aerosol-generating article. The cartridge may include at least 6 grams, at least 7 grams, at least 8 grams, or at least 9 grams of aerosol-forming substrate. The cartridge may include up to 15 grams, up to 12 grams; up to 11 grams, or up to 10 grams of aerosol-forming substrate. Preferably, from about 7 grams to about 13 grams of aerosol-forming substrate is provided in the aerosol-generating article.

In some preferred embodiments, the aerosol-forming substrate may comprise tobacco, sugar and an aerosol-former. In these embodiments, the aerosol-forming substrate may comprise between 10 percent and 40 percent by weight of tobacco. In these embodiments, the aerosol-forming substrate may comprise between 20 percent and 50 percent by weight of sugar. In these embodiments, the aerosol-forming substrate may comprise between 25 percent and 55 percent by weight of aerosol-former.

Below, there is provided a non-exhaustive list of non-limiting examples. Any one or more of the features of these examples may be combined with any one or more features of another example, embodiment, or aspect described herein.

EX1. An aerosol-generating system comprising:
an aerosol-forming substrate;
a first electrode and a second electrode spaced apart from the first electrode; and
an aerosol-generating device comprising:
   a power supply; and
   a controller configured to connect to the first electrode and the second electrode,
wherein:
the system includes a capacitor comprising the first electrode, the second electrode, and at least a portion of the aerosol-forming substrate; and
the controller is configured to:
   supply an alternating voltage to the first electrode and the second electrode for dielectrically heating the aerosol-forming substrate;
   measure or determine an electrical property between the first electrode and the second electrode; and
   control heating of the aerosol-forming substrate based on the measured or determined electrical property.

EX2. An aerosol-generating system according to example EX1, wherein the controller is configured to control the alternating voltage supplied to the first electrode and the second electrode to control heating of the aerosol-forming substrate based on the measured or determined electrical property.

EX3. An aerosol-generating system according to examples EX1 or EX2, wherein the controller is configured to supply an alternating voltage to the first electrode and the second electrode for measuring or determining the electrical property between the first electrode and the second electrode.

EX4. An aerosol-generating system according to example EX3, wherein the frequency of the alternating voltage supplied to the first electrode and the second electrode for measuring or determining the electrical property between the first electrode and the second electrode is between about 10 Hz and about 100 GHz, and preferably between about 10 kHz, and about 100 MHz.

EX5. An aerosol-generating system according to any one of examples EX1 to EX4 wherein the controller is configured to determine the impedance between the first electrode and the second electrode.

EX6. An aerosol-generating system according to any one of examples EX3 or EX4, wherein the controller is configured to measure an alternating electrical current supplied to the first electrode and the second electrode when the alternating voltage for measuring or determining the electrical property between the first electrode and the second electrode is supplied.

EX7. An aerosol-generating system according to example EX6, wherein the controller is configured to control heating of a portion of the aerosol-forming substrate based on the measured alternating current.

EX8. An aerosol-generating system according to example EX6, wherein the controller is configured to determine the impedance between the first electrode and the second electrode based on the measured alternating current, and wherein the controller is configured to control heating of the aerosol-forming substrate based on the determined impedance.

EX9. An aerosol-generating system according to any one of examples EX1 to EX8, wherein the power supply is configured to supply a direct voltage, wherein a DC/AC converter is arranged at an output of the power supply for supplying an alternating voltage to the first electrode and the second electrode, and wherein the controller is configured to control the supply of the alternating voltage from the DC/AC converter to the first electrode and the second electrode.

EX10. An aerosol-generating system according to any one of examples EX1 to EX4, wherein the power supply is configured to supply a direct voltage, wherein a DC/AC converter is arranged at an output of the power supply for supplying an alternating voltage to the first electrode and the second electrode, wherein the controller is configured to control the supply of the alternating voltage from the DC/AC converter to the first electrode and the second electrode, and wherein the controller is configured to measure the direct electrical current supplied to the DC/AC converter.

EX11. An aerosol-generating system according to example EX10, wherein the controller is configured to control heating of the aerosol-forming substrate based on the measured direct current.

EX12. An aerosol-generating system according to example EX10, wherein the controller is configured to determine the impedance between the first electrode and the second electrode based on the measured direct current, and wherein the controller is configured to control heating of the aerosol-forming substrate based on the determined impedance.

EX13. An aerosol-generating system according to any one of examples EX1 to EX12, wherein a portion of the aerosol-forming substrate is removably receivable between the first electrode and the second electrode, and wherein the controller is configured to determine whether aerosol-forming substrate is received between the first electrode and the second electrode based on the measured or determined electrical property between the first electrode and the second electrode.

EX14. An aerosol-generating system according to example EX13, wherein the controller is configured to prevent heating of the aerosol-forming substrate when it is determined that aerosol-forming substrate is not received between the first electrode and the second electrode.

EX15. An aerosol-generating system according to any one of examples EX1 to EX14, wherein the controller is configured to determine the temperature of the aerosol-forming substrate based on the measured or determined electrical property between the first electrode and the second electrode.

EX16. An aerosol-generating system according to any one of examples EX1 to EX15, wherein the controller is configured to determine a physical characteristic of the aerosol-forming substrate based on the measured or determined electrical property.

EX17. An aerosol-generating system according to any one of examples EX1 to EX16, wherein the aerosol-forming substrate is removably receivable between the first electrode and the second electrode, and wherein the controller is configured to determine whether the aerosol-forming substrate received between the first electrode and the second electrode is authentic based on the measured or determined electrical property.

EX18. An aerosol-generating system according to example EX17, wherein the controller is configured to prevent heating of the aerosol-forming substrate when it is determined that the aerosol-forming substrate received between the first electrode and the second electrode is not authentic.

EX19. An aerosol-generating system according to any one of examples EX1 to EX18, wherein an inductor is arranged between the power supply, and the capacitor comprising the first electrode, the second electrode and at least a portion of the aerosol-forming substrate.

EX20. An aerosol-generating system according to example EX19, wherein the inductor and the capacitor comprising the first electrode, the second electrode and at least a portion of the aerosol-forming substrate form a resonant circuit having a resonant frequency, wherein the resonant frequency is dependent on the electrical property between the first electrode and the second electrode.

EX21. An aerosol-generating system according to example EX20, wherein the controller is configured to supply the alternating voltage to the first electrode and the second electrode for heating the aerosol-forming substrate at the resonant frequency of the resonant circuit.

EX22. An aerosol-generating system according to any one of examples EX1 to EX21, wherein the aerosol-generating device comprises an oscillation circuit arranged between the controller and the capacitor comprising the first electrode, the second electrode and at least a portion of the aerosol-forming substrate, and wherein the controller is configured to control the oscillation circuit to supply the alternating voltage to the first electrode and the second electrode for heating the aerosol-forming substrate.

EX23. An aerosol-generating system according to example EX22, wherein the oscillation circuit is configured to supply the alternating voltage to the first electrode and the second electrode for heating the aerosol-forming substrate.

EX24. An aerosol-generating system according to example EX23, wherein the alternating electromagnetic field between the first electrode and the second electrode dielectrically heats the aerosol-forming substrate.

EX25. An aerosol-generating system according to any one of examples EX1 to EX24, wherein the first electrode and the second electrode are planar electrodes.

EX26. An aerosol-generating system according to example EX25, wherein the first planar electrode extends substantially in a first plane, and the second planar electrode extends substantially in a second plane, and wherein the first plane is substantially parallel to the second plane.

EX27. An aerosol-generating system according to any one of examples EX1 to EX24, wherein the first electrode circumscribes the second electrode when the aerosol-generating article is received by the aerosol-generating device.

EX28. An aerosol-generating system according to example EX27, wherein the first electrode is an annular electrode comprising an inner cavity, and wherein the second electrode is received in the inner cavity of the first electrode when the aerosol-generating article is received by the aerosol-generating device.

EX29. An aerosol-generating system according to any one of examples EX1 to EX28, wherein the aerosol-generating system comprises an aerosol-generating article comprising the aerosol-forming substrate.

EX30. An aerosol-generating system according to example EX29, wherein the aerosol-generating device is configured to receive at least a portion of the aerosol-generating article.

EX31. An aerosol-generating system according to examples EX29 or EX30, wherein the aerosol-generating device comprises a cavity configured to receive at least a portion of the aerosol-generating article.

EX32. An aerosol-generating system according to any one of examples EX29 to EX31, wherein the aerosol-generating article comprises a wrapper circumscribing the aerosol-forming substrate.

EX33. An aerosol-generating system according to example EX32, wherein the wrapper comprises an electrically insulative material.

EX34. An aerosol-generating system according to any one of examples EX1 to EX33, wherein the aerosol-generating device comprises the first electrode and the second electrode.

EX35. An aerosol-generating system according to any one of examples EX29 to EX33, wherein the aerosol-generating article comprises the first electrode and the second electrode.

EX36. An aerosol-generating system according to any one of examples EX29 to EX33, wherein the aerosol-generating device comprises one of the first electrode and the second electrode, and wherein the aerosol-generating article comprises the other one of the first electrode and the second electrode.

EX37. An aerosol-generating device for dielectrically heating an aerosol-forming substrate, the aerosol-generating device comprising:
a first electrode and a second electrode spaced apart from the first electrode,
a power supply; and
a controller configured to connect to the first electrode and the second electrode,
wherein:
the first electrode and the second electrode are configured to form a capacitor with a portion of the aerosol-forming substrate to be dielectrically heated;
the controller is configured to:
   supply an alternating voltage to the first electrode and the second electrode for dielectrically heating a portion of the aerosol-forming substrate;
   measure or determine an electrical property between the first electrode and the second electrode; and
   control heating of the aerosol-forming substrate based on the measured or determined electrical property.

EX38. An aerosol-generating system according to example EX37, wherein the controller is configured to control the alternating voltage supplied to the first electrode and the second electrode to control heating of the aerosol-forming substrate based on the measured or determined electrical property.

EX39. An aerosol-generating device according to examples EX37 or EX38, wherein the controller is configured to supply an alternating voltage to the first electrode and the second electrode for measuring or determining the electrical property between the first electrode and the second electrode.

EX40. An aerosol-generating device according to example EX39, wherein the frequency of the alternating voltage supplied to the first electrode and the second electrode for measuring or determining the electrical property between the first electrode and the second electrode is between about 10 Hz and about 100 GHz, and preferably between about 10 kHz, and about 100 MHz.

EX41. An aerosol-generating device according to any one of examples EX37 to EX40 wherein the controller is configured to determine the impedance between the first electrode and the second electrode.

EX42. An aerosol-generating device according to any one of examples EX39 or EX40, wherein the controller is configured to measure an alternating electrical current supplied to the first electrode and the second electrode when the alternating voltage for measuring or determining the electrical property between the first electrode and the second electrode is supplied.

EX43. An aerosol-generating device according to example EX42, wherein the controller is configured to control heating of a portion of the aerosol-forming substrate based on the measured alternating current.

EX44. An aerosol-generating device according to example EX42, wherein the controller is configured to determine the impedance between the first electrode and the second electrode based on the measured alternating current, and wherein the controller is configured to control heating of a portion of the aerosol-forming substrate based on the determined impedance.

EX45. An aerosol-generating device according to any one of examples EX37 to EX44, wherein the power supply is configured to supply a direct voltage, wherein a DC/AC converter is arranged at an output of the power supply for supplying an alternating voltage to the first electrode and the second electrode, and wherein the controller is configured to control the supply of the alternating voltage from the DC/AC converter to the first electrode and the second electrode.

EX46. An aerosol-generating device according to any one of examples EX37 to EX40, wherein the power supply is configured to supply a direct voltage, wherein a DC/AC converter is arranged at an output of the power supply for supplying an alternating voltage to the first electrode and the second electrode, wherein the controller is configured to control the supply of the alternating voltage from the DC/AC converter to the first electrode and the second electrode, and wherein the controller is configured to measure the direct electrical current supplied to the DC/AC converter.

EX47. An aerosol-generating device according to example EX46, wherein the controller is configured to control heating of a portion of the aerosol-forming substrate based on the measured direct current.

EX48. An aerosol-generating device according to example EX46, wherein the controller is configured to determine the impedance between the first electrode and the second electrode based on the measured direct current, and wherein the controller is configured to control heating of a portion of the aerosol-forming substrate based on the determined impedance.

EX49. An aerosol-generating device according to any one of examples EX37 to EX48, wherein a portion of the aerosol-forming substrate is removably receivable between the first electrode and the second electrode, and wherein the controller is configured to determine whether aerosol-forming substrate is received between the first electrode and the second electrode based on the measured or determined electrical property between the first electrode and the second electrode.

EX50. An aerosol-generating device according to example EX49, wherein the controller is configured to prevent heating of a portion of the aerosol-forming substrate when it is determined that aerosol-forming substrate is not received between the first electrode and the second electrode.

EX51. An aerosol-generating device according to any one of examples EX37 to EX50, wherein the controller is configured to determine the temperature of a portion of the aerosol-forming substrate to be dielectrically heated based on the measured or determined electrical property between the first electrode and the second electrode.

EX52. An aerosol-generating device according to any one of examples EX37 to EX51, wherein the controller is configured to determine a physical characteristic of the aerosol-forming substrate based on the measured or determined electrical property.

EX53. An aerosol-generating device according to any one of examples EX37 to EX52, wherein the aerosol-forming substrate is removably receivable between the first electrode and the second electrode, and wherein the controller is configured to determine whether the aerosol-forming substrate received between the first electrode and the second electrode is authentic based on the measured or determined electrical property.

EX54. An aerosol-generating device according to example EX53, wherein the controller is configured to prevent heating of the aerosol-forming substrate received between the first electrode and the second electrode when it is determined that the aerosol-forming substrate received between the first electrode and the second electrode is not authentic.

EX55. An aerosol-generating device according to any one of examples EX37 to EX54, wherein an inductor is arranged between the power supply, and the capacitor comprising the first electrode, the second electrode and at least a portion of the aerosol-forming substrate.

EX56. An aerosol-generating device according to example EX55, wherein the inductor and the capacitor comprising the first electrode, the second electrode and at least a portion of the aerosol-forming substrate form a resonant circuit having a resonant frequency, wherein the resonant frequency is dependent on the electrical property between the first electrode and the second electrode.

EX57. An aerosol-generating device according to example EX56, wherein the controller is configured to supply the alternating voltage to the first electrode and the second electrode for heating at least a portion of the aerosol-forming substrate at the resonant frequency of the resonant circuit.

EX58. An aerosol-generating device according to any one of examples EX37 to EX57, wherein the aerosol-generating device comprises an oscillation circuit arranged between the controller and the capacitor comprising the first electrode, the second electrode and at least a portion of the aerosol-forming substrate, and wherein the controller is configured to control the oscillation circuit to supply the alternating voltage to the first electrode and the second electrode for heating the aerosol-forming substrate.

EX59. An aerosol-generating device according to example EX58, wherein the oscillation circuit is configured to supply the alternating voltage to the first electrode and the second electrode for heating the aerosol-forming substrate, the radio frequency voltage between the first electrode and the second electrode generating an alternating radio frequency electromagnetic field between the first electrode and the second electrode for heating the aerosol-forming substrate.

EX60. An aerosol-generating device according to example EX59, wherein the alternating radio frequency electromagnetic field between the first electrode and the second electrode dielectrically heats the aerosol-forming substrate.

EX61. An aerosol-generating device according to any one of examples EX37 to EX60, wherein the first electrode and the second electrode are planar electrodes.

EX62. An aerosol-generating device according to example EX61, wherein the first planar electrode extends substantially in a first plane, and the second planar electrode extends substantially in a second plane, the first plane being substantially parallel to the second.

EX63. An aerosol-generating device according to any one of examples EX37 to EX60, wherein the first electrode circumscribes the second electrode.

EX64. An aerosol-generating device according to example EX63, wherein the first electrode is an annular electrode comprising an inner cavity, and wherein the second electrode is received in the inner cavity of the first electrode.

EX65. An aerosol-generating system comprising:
an aerosol-forming substrate;
a first electrode and a second electrode spaced apart from the first electrode; and
an aerosol-generating device comprising:
   a power supply; and
   a controller configured to connect to the first electrode and the second electrode,
wherein:
the system includes a capacitor comprising the first electrode, the second electrode, and at least a portion of the aerosol-forming substrate; and
the controller is configured to:
   measure or determine an electrical property between the first electrode and the second electrode; and
   determine the temperature of the aerosol-forming substrate between the first electrode and the second electrode based on the determined electrical property between the first electrode and the second electrode.

EX66. An aerosol-generating system according to example EX65, wherein the controller is further configured to supply an alternating voltage to the first electrode and the second electrode for heating the aerosol-forming substrate when the aerosol-generating article is received by the aerosol-generating device.

EX67. An aerosol-generating system comprising:
an aerosol-forming substrate;
a first electrode and a second electrode spaced apart from the first electrode; and
an aerosol-generating device comprising:
   a power supply; and
   a controller configured to connect to the first electrode and the second electrode,
wherein:
the system comprises a resonant circuit comprising the first electrode, the second electrode, and at least a portion of the aerosol-forming substrate, the resonant circuit having a resonant frequency; and
the controller is configured to:
measure or determine an electrical property between the first electrode and the second electrode; and
determine the resonant frequency of the resonant circuit based on the measured or determined electrical property between the first electrode and the second electrode.

EX68. An aerosol-generating system according to example EX67, wherein the controller is configured to determine whether the aerosol-generating article is authentic based on the determined resonant frequency.

EX69. An aerosol-generating system according to example EX67 or EX68, wherein the controller is configured to supply an alternating voltage to the first electrode and the second electrode for heating the aerosol-forming substrate when the aerosol-generating article is received by the aerosol-generating device.

EX70. An aerosol-generating system according to example EX69, wherein the controller is configured to supply an alternating voltage to the first electrode and the second electrode for heating the aerosol-forming substrate at a frequency dependent on the determined resonant frequency of the resonant circuit.

Embodiments of the present disclosure will now be described, by way of example only, with reference to the accompanying drawings, in which:

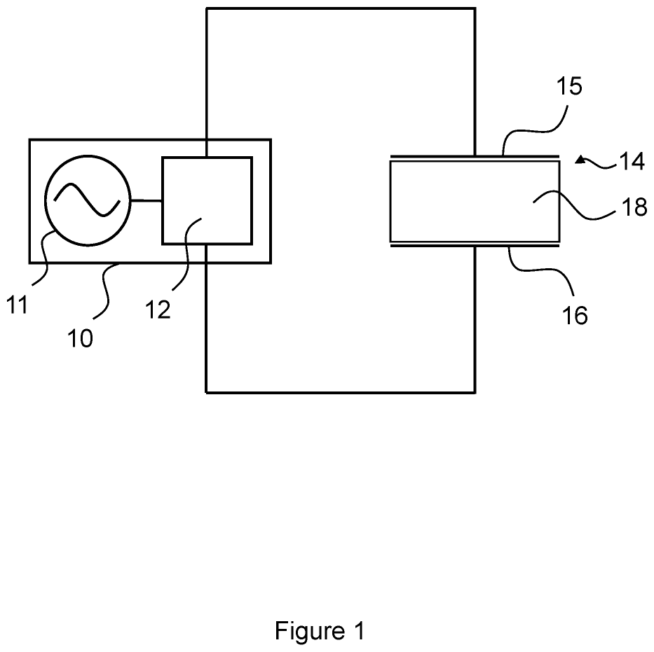

FIG. 1 is a schematic illustration of a system for dielectrically heating a substrate;

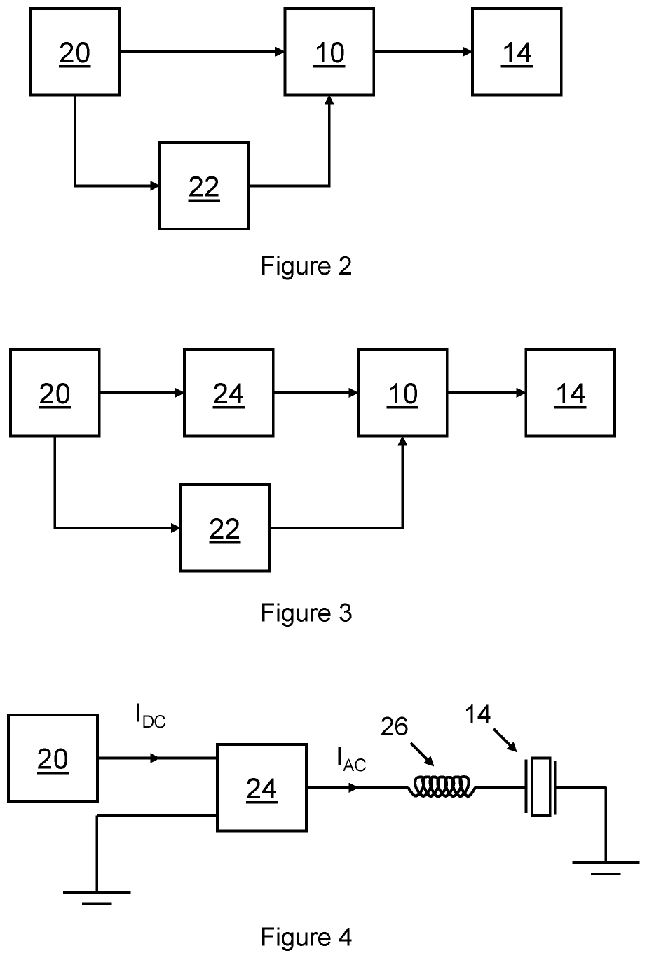

FIG. 2 is a schematic illustration of a control system for an aerosol-generating system having a dielectric heating arrangement according to an embodiment of the disclosure;

FIG. 3 is a schematic illustration of a control system for an aerosol-generating system having a dielectric heating arrangement according to an embodiment of the disclosure;

FIG. 4 is a schematic illustration of a control system for an aerosol-generating system having a dielectric heating arrangement according to an embodiment of the disclosure;

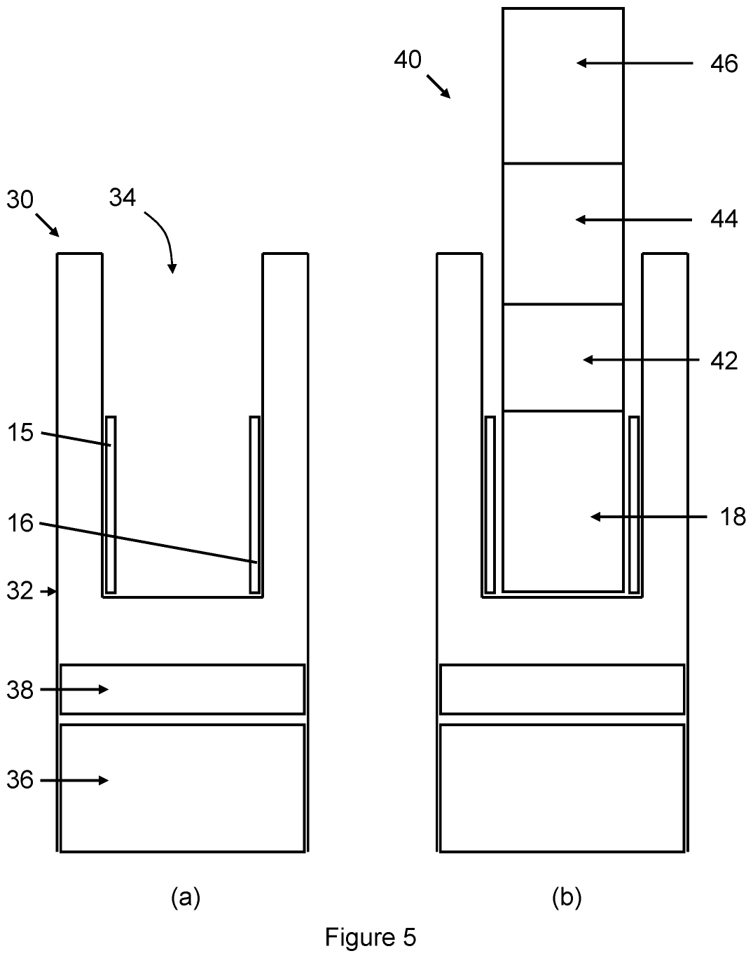

FIG. 5 is a schematic illustration of an aerosol-generating system according to an embodiment of the disclosure;

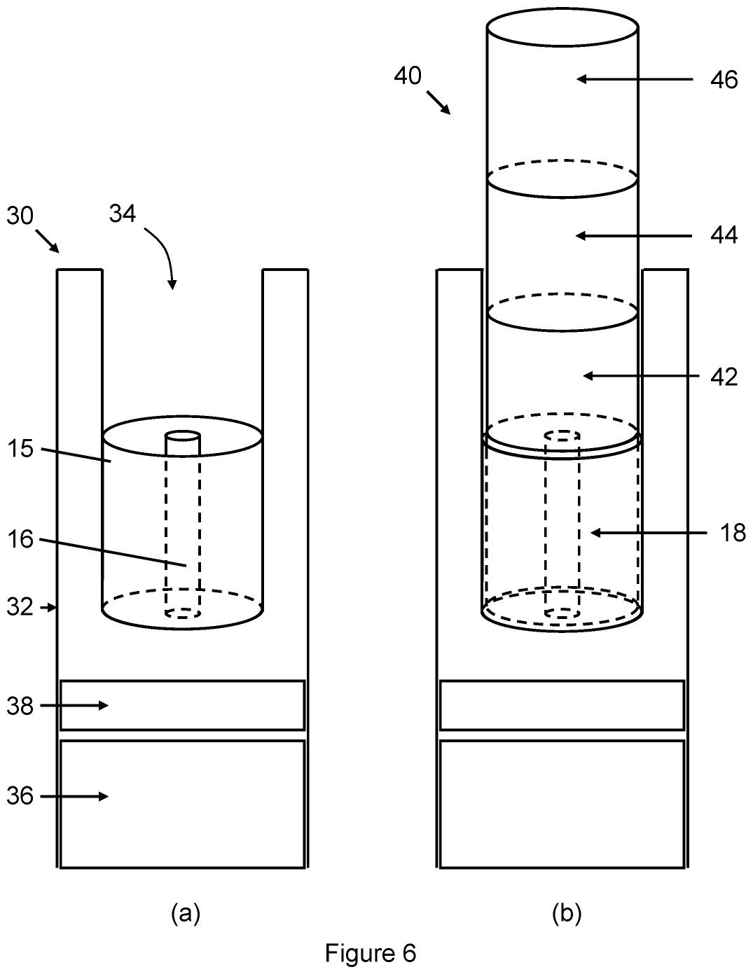

FIG. 6 is a schematic illustration of an aerosol-generating system according to an embodiment of the disclosure;

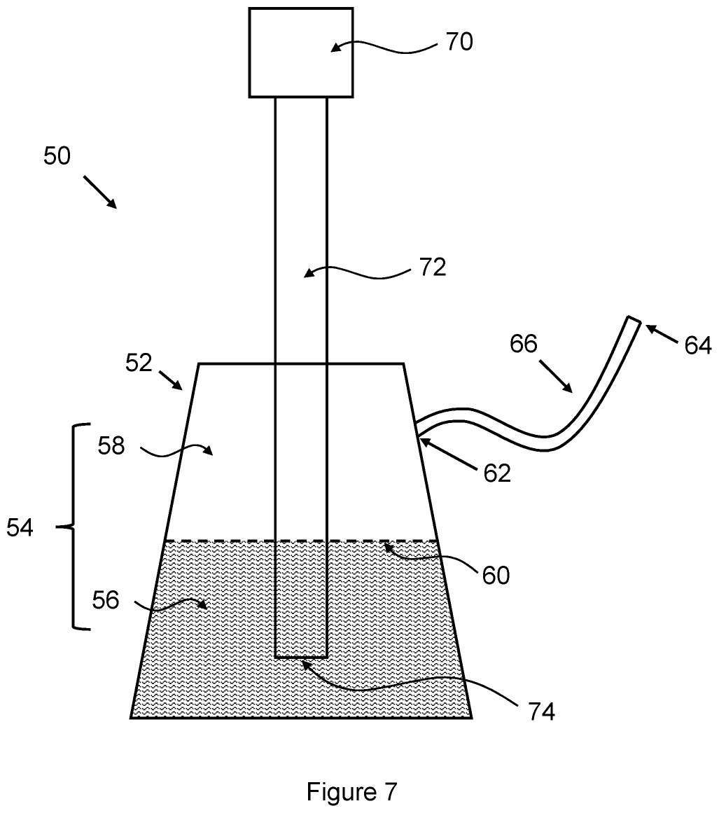

FIG. 7 is a schematic illustration of an embodiment of a shisha system having a dielectric heating system;

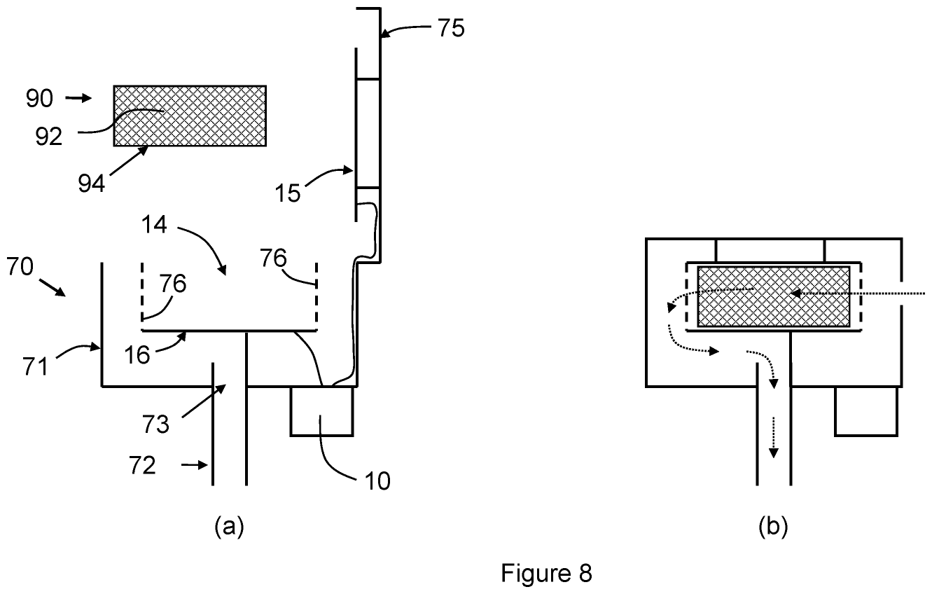

FIG. 8 is a schematic illustration of a heating unit of a shisha device and an aerosol-generating article configured for use with the shisha device according to an embodiment of the disclosure; and

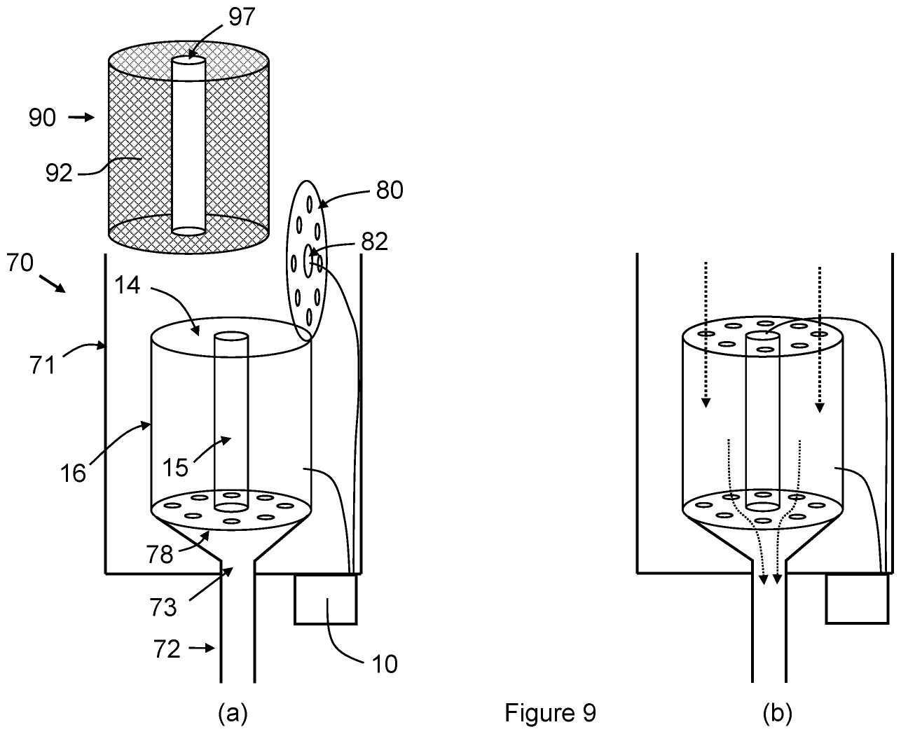

FIG. 9 is a schematic illustration of a heating unit of a shisha device and an aerosol-generating article configured for use with the shisha device according to an embodiment of the disclosure.

FIG. 1 is a schematic illustration of a system for dielectrically heating an aerosol-forming substrate using an alternating voltage. The system comprises an oscillation circuit 10, including a radio frequency (RF) signal generator 11 and a phase shift network 12, and a capacitor 14. The capacitor 14 comprises a first electrode 15, a second electrode 16 spaced apart from the first electrode 15, and an aerosol-forming substrate 18 arranged between the first electrode 15 and the second electrode 16. The aerosol-forming substrate 18 acts as the dielectric of the capacitor 14. The oscillation circuit 10 supplies an alternating voltage to the first electrode 15 and the second electrode 16, which generates an alternating electromagnetic field between the first electrode 15, and the second electrode 16. Polar molecules within the aerosol-forming substrate 18 align with the alternating electromagnetic field between the first electrode 15 and the second electrode 16, and so are agitated by the electromagnetic field as it oscillates. This causes an increase in temperature of the aerosol-forming substrate 18. This kind of heating has the advantage that it is uniform throughout the aerosol-forming substrate 18 (provided that the polar molecules are uniformly distributed). It also has the advantage of reducing the likelihood of combustion of the substrate in contact with the first electrode 15 and the second electrode 16 compared to a conventional heating element that transfers heat to the substrate via conduction.

The embodiment of FIG. 1 comprises a phase shift network 12; however, it will be appreciated that in other embodiments according to the disclosure one of the first electrode 15 and the second electrode 16 may be connected to ground.

FIGS. 2, 3 and 4 are schematic illustrations of electrical systems for aerosol-generating systems having dielectric heating arrangements according to embodiments of the disclosure.

The system of FIG. 2 comprises a DC power supply 20, such as a lithium-ion battery, with an output connected to an oscillation circuit 10. The DC power supply 20 is configured to supply a DC voltage to the oscillation circuit 10. The oscillation circuit 10 is connected to a capacitor 14, comprising a first electrode, a second electrode spaced from the first electrode, and an aerosol-forming substrate. The oscillation circuit 10 is configured to supply an alternating voltage to the capacitor 14. A controller 22 is connected to the DC power supply 20 and the oscillation circuit 10, and is configured to control the supply of the alternating voltage to the capacitor 14. When an alternating voltage is supplied to the capacitor 14, an alternating electromagnetic field is generated between the first electrode and the second electrode. The controller 22 is configured to supply a first alternating voltage from the oscillation circuit 10 to the capacitor 14 for heating the aerosol-forming substrate. The controller 22 is also configured to supply a second alternating voltage from the oscillation circuit 10 to the capacitor 14 for measuring or determining an electrical property between the first electrode and the second electrode. Measuring or determining an electrical property between the first electrode and the second electrode measures or determines an electrical property of the aerosol-forming substrate of the capacitor 14.

The system of FIG. 3 is substantially similar to the embodiment of FIG. 2, and like features are denoted with like reference numerals. The embodiment of FIG. 3 comprises a DC power supply 20 with an output connected to a DC/AC converter 24 for supplying a DC voltage to the DC/AC converter 24. An output of the DC/AC converter 24 is connected to an oscillation circuit 10 for supplying an alternating voltage to the oscillation circuit 10. The oscillation circuit 10 is connected to a capacitor 14, comprising a first electrode, a second electrode spaced from the first electrode, and an aerosol-forming substrate. The oscillation circuit 10 is configured to supply an alternating voltage to the capacitor 14. When an alternating voltage is supplied to the capacitor 14, an alternating electromagnetic field is generated between the first electrode and the second electrode. A controller 22 is connected to the power supply 20 and the oscillation circuit 10 for controlling the alternating voltage supplied from the oscillation circuit 10 to the capacitor 14. The controller 22 is configured to supply a first alternating voltage to the capacitor 14 for heating the aerosol-forming substrate. The controller 22 is also configured to supply a second alternating voltage to the capacitor 14 for measuring or determining an electrical property between the first electrode and the second electrode. Measuring or determining an electrical property between the first electrode and the second electrode measures or determines an electrical property of the aerosol-forming substrate.

In this embodiment, the DC/AC converter 24 does not form part of the oscillation circuit 10, and is not controlled by the controller 22. It will be appreciated that in the embodiment of FIG. 2 above, the oscillation circuit 10 comprises a DC/AC converter, and the DC/AC converter is controlled by the controller 22 along with the oscillation circuit 10.

FIG. 4 shows a schematic illustration of a simplified electrical system, such as the system of FIG. 2 or 3, wherein components such as the controller are not shown. The system of FIG. 4 comprises a DC power supply 20 connected to a DC/AC converter 24. The DC power supply 20 is configured to supply a DC voltage and a DC current I_{DC} to the DC/AC converter 24. An output of the DC/AC converter 24 is connected to a capacitor 14, and is configured to supply an alternating voltage and an alternating current I_{AC} to the capacitor 14. In this embodiment, an inductor 26 is arranged in series with the DC/AC converter 24 and the capacitor 14. As shown in FIG. 4, the inductor 26 is arranged between the output of the DC/AC converter 24 and the capacitor 14. However, the inductor 26 may be arranged after the DC/AC converter 24 and the capacitor 14. The inductor 26 is provided for impedance matching with the output of the DC/AC converter. One or more resistors (not shown) may also be provided between the output of the DC/AC converter 24 and the capacitor 14, or after the DC/AC converter 24 and the capacitor 14, for impedance matching.

In this embodiment, the inductor 26 and the capacitor 14 form a resonant circuit, having a resonant frequency. The resonant frequency of the resonant circuit is dependent on the electrical properties of the aerosol-forming substrate that forms the capacitor 14 with the first electrode and the second electrode. When the DC/AC converter 26 supplies the alternating voltage to the capacitor 14 at the resonant frequency of the resonant circuit, the impedance of the resonant circuit is significantly reduced compared to the impedance at frequencies away from the resonant frequency. The controller is configured to supply the alternating voltage to the capacitor for heating the aerosol-forming substrate at the resonant frequency of the resonant circuit.

In some embodiments, the controller (not shown in FIG. 4) may be configured to directly measure the alternating current I_{AC} supplied to the capacitor 14. The controller may be configured to compare the alternating current I_{AC} to expected values of alternating current for known aerosol-forming substrates, and control the alternating current I_{AC} supplied to the capacitor 14 for heating the aerosol-forming substrate based on the measured alternating current I_{AC}, in a feedback loop. Preferably, the controller is configured to determine the impedance of the capacitor 14 based on the measured alternating current I_{AC}, and to control the alternating current I_{AC} supplied to the capacitor 14 based on the determined impedance. The impedance of the capacitor 14 is dependent on the impedance of the aerosol-forming substrate forming the capacitor.

In this embodiment, the controller (not shown in FIG. 4) is configured to measure the direct current I_{DC} supplied to the DC/AC converter 24. The direct current I_{DC} supplied to the DC/AC converter 24 provides an indication of the alternating current I_{AC} supplied to the capacitor 14, and enables the alternating current I_{AC} to be estimated. In turn, the controller may also be configured to determine an estimate of the impedance of the capacitor 14 based on a measurement of the direct current I_{DC}. The impedance of the capacitor 14 is dependent on the impedance of the aerosol-forming substrate forming the capacitor. The controller may be configured to control the alternating current supplied to the capacitor 14 based on the measured direct current I_{DC} supplied to the DC/AC converter 24, or based on the estimated impedance of the capacitor 14 determined from the measured direct current I_{DC}. Measuring the direct current I_{DC} provides a less precise indication of the electrical property between the first electrode and the second electrode than measuring the alternating current I_{AC}, but requires less complex and expensive circuitry than measuring the alternating current I_{AC}, making the system more robust, less complex and less expensive.

The controller may be configured to use the measured alternating current I_{AC}, the measured direct current I_{DC}, the determined impedance of the capacitor 14 based on the measured alternating current I_{AC}, or the determined impedance of the capacitor 14 based on the measured direct current I_{DC} in a number of ways.

For example, the controller may be configured to supply an alternating voltage to the capacitor 14 for the purpose of measuring the direct current I_{DC} supplied to the DC/AC converter 24 or the indirect current I_{AC} supplied to the capacitor 14 before supplying an alternating voltage to the capacitor 14 for the purpose of heating the aerosol-forming substrate. If aerosol-forming substrate is not present in the capacitor 14, between the first electrode and the second electrode, the measured direct current I_{DC} or alternating current I_{AC} will be different than expected, as the impedance of the capacitor 14 is dependent on the electrical properties of the material between the first electrode and the second electrode. Accordingly, the controller may be configured to determine whether the aerosol-forming substrate is present between the first electrode and the second electrode based on the measured direct current I_{DC} or alternating current I_{AC}, and may be further configured to prevent heating of the aerosol-forming substrate if it is determined that the aerosol-forming substrate is not located between the first electrode and the second electrode.

Similarly, the controller may be configured to determine the type or composition of aerosol-forming substrate between the first electrode and the second electrode based on the measured direct current I_{DC} or alternating current I_{AC}. This may enable the controller to determine whether the aerosol-forming substrate is an authentic aerosol-forming substrate that is suitable to be heated by the system. The controller may be configured to prevent heating of the aerosol-forming substrate if it is determined that the aerosol-forming substrate is not authentic. In some embodiments, the controller is configured to determine whether the aerosol-forming substrate is authentic by determining the resonant frequency of the resonant circuit. Since the impedance of the capacitor 14 is particularly low when an alternating voltage is supplied to the resonant circuit at the resonant frequency of the resonant circuit, the measured currents, and determined impedances, provide an indication of whether the frequency of the alternating voltage is the resonant frequency of the resonant circuit. Accordingly, the controller may be configured to determine whether the aerosol-forming substrate has the expected electrical properties, and as such, is authentic, based on a determination of the resonant frequency of the resonant circuit.

In addition, the controller may be configured to differentiate between different compositions of aerosol-forming substrate based on the measured direct current I_{DC} or alternating current I_{AC}. The controller may be further configured to control the heating of the aerosol-forming substrate based on based on the measured direct current I_{DC} or alternating current I_{AC}. For example, the controller may be configured to heat different compositions of aerosol-forming substrate to different temperatures, such that each aerosol-forming substrate is heated to the optimal temperature for aerosol generation. The controller may be configured to vary the alternating voltage supplied to the first electrode and the second electrode for heating the aerosol-forming substrate based on the measured direct current I_{DC} or alternating current I_{AC}.

The electrical properties of the aerosol-forming substrate may also vary depending on the temperature of the aerosol-forming substrate. Accordingly, the controller may be further configured to determine the temperature of the aerosol-forming substrate based on the measured direct current I_{DC} or alternating current I_{AC}. The controller may be further configured to control the heating of the aerosol-forming substrate based on based on the determined temperature. The controller may be configured to vary the alternating voltage supplied to the first electrode and the second electrode for heating the aerosol-forming substrate based on the determined temperature.

The embodiments described with reference to FIGS. 5 to 9 use the basic dielectric heating and control principles illustrated in FIGS. 1 to 4.

FIG. 5 is a schematic illustration of an aerosol-generating system according to an embodiment of this disclosure

The aerosol-generating system comprises an aerosol-generating device 30, and an aerosol-generating article 40. The aerosol-generating device comprises a housing 32 defining an article cavity 34. The aerosol-generating device 30 is configured to receive an end portion of the aerosol-generating article 40 in the article cavity 34. The aerosol-generating device comprises a DC power supply 36, in the form of a rechargeable lithium-ion battery, and circuitry 38. The circuitry 38 comprises an electrical system having a dielectric heating arrangement as described above with reference to FIGS. 1 to 4, including a controller. A first electrode 15, and a second electrode 16 are provided at opposite sides of the article cavity 34. The first electrode 15 and the second electrode 16 are substantially identical planar electrodes, forming parallel plates spaced apart by the width of the article cavity 34. The first electrode 15 and the second electrode 16 are connected to the circuitry 38, and form part of the electrical system. The article cavity 34 comprises an open end for insertion and removal of the aerosol-generating article 40, and a closed end opposite the open end. The first electrode 15 and the second electrode 16 are located towards the closed end of the article cavity 34.

The aerosol-generating article 40 comprises a plurality of components arranged end to end in the form of a cylindrical rod, similar to a conventional cigarette. The aerosol-generating article comprises an aerosol-forming substrate 18 at a distal end, a cooling element 42, a spacing element 44, and a mouthpiece filter 46 at a proximal end. An outer wrapper (not shown) of cigarette paper is tightly wrapped around the components and holds the components of the aerosol-generating article 40 together. The aerosol-forming substrate 18 comprises a gathered and crimped sheet of homogenised tobacco.

As shown in FIG. 5b, the distal end of the aerosol-generating article 40 is receivable in the article cavity 34, with the aerosol-forming substrate 18 arranged between the first electrode 15 and the second electrode 16, and the first and second electrodes extending substantially the length of the aerosol-forming substrate 18. When the aerosol-forming substrate is arranged in the article cavity 34, between the first electrode 15 and the second electrode 16, the first electrode 15, the second electrode 16 and the aerosol-forming substrate 18 form a capacitor.

The width of the aerosol-generating article 40 is slightly greater than the spacing between the first electrode 15 and the second electrode 16, such that the distal end of the aerosol-generating article 40 is slightly compressed between the first electrode 15 and the second electrode 16. This ensures that there is minimal air between the first electrode 15 and the second electrode 16 when the aerosol-generating article 40 is received in the article cavity 34. Minimising the amount of air between the first electrode 15 and the second electrode 16 when the aerosol-generating article 40 is received in the article cavity 34 may improve the accuracy of any measurements or determinations of the electrical properties of the aerosol-forming substrate 18 performed by the aerosol-generating device 30.

The aerosol-generating system is configured for dielectric heating of the aerosol-forming substrate 18, by suppling an appropriate alternating voltage to the first electrode 15 and the second electrode 16. In use, when an alternating voltage is supplied to the first electrode 15 and the second electrode 16 for heating the aerosol-forming substrate 18, an alternating electromagnetic field is generating in the article cavity 34 between the first electrode 15 and the second electrode 16, which agitates polar molecules in the aerosol-forming substrate, and dielectrically heats the aerosol-forming substrate.

In use, the distal end of the aerosol-generating article 40 is received in the article cavity 34, and a user may draw on the mouthpiece filter 46 of the aerosol-generating article 40 to receive aerosol from the aerosol-generating system. An alternating voltage is supplied to the first electrode 15 and the second electrode 16 for heating the aerosol-forming substrate, and the heated aerosol-forming substrate releases volatile compounds that are entrained in the airflow drawn through the article 40 by a user, which cool in the cooling element 42, spacing element 44, and mouthpiece filter 46 and condense to form an aerosol that is inhaled by the user.

The aerosol-generating system is also configured for measuring an electrical property of the aerosol-forming substrate 18 using the electrodes that are employed for dielectric heating of the aerosol-forming substrate 18. In this embodiment, the aerosol-generating system is configured to determine the presence of the aerosol-forming substrate 18 between the first electrode 15 and the second electrode 16, is configured to determine the composition and authenticity of the aerosol-forming substrate 18, and is also configured to control the heating of the aerosol-forming substrate 18 based on the measured electrical property of the aerosol-forming substrate.

FIG. 6 is a schematic illustration of an aerosol-generating system according to another embodiment of this disclosure

The aerosol-generating system of FIG. 6 is substantially similar to the aerosol-generating system of FIG. 5, and like features are denoted by like reference numerals.

The aerosol-generating system of FIG. 5 comprises an aerosol-generating device 30, and an aerosol-generating article 40. The aerosol-generating device 40 of FIG. 6 differs from the aerosol-generating device of FIG. 5 in that the first electrode 15 of the aerosol-generating device of FIG. 6 is annular and cylindrical, having an inner passage configured to receive a distal portion of the aerosol-generating article 40. The inner passage circumscribes the article cavity 34. The aerosol-generating device 40 of FIG. 6 also differs from the aerosol-generating device 40 of FIG. 5, in that the second electrode 16 of the aerosol-generating device of FIG. 6 is cylindrical, and arranged inside the inner passage of the first electrode 15. The second electrode 16 is configured to pierce the aerosol-forming substrate 16 of the aerosol-generating article 40 when the distal end of the aerosol-generating article 40 is received in the article cavity 34. The aerosol-generating article 40 of FIG. 6 is identical to the aerosol-generating article 40 of FIG. 5.

Both embodiments shown in FIGS. 5 and 6 comprise an aerosol-generating device 30 including the first electrode 15 and the second electrode 16. It will be appreciated that other embodiments are also envisaged in which the aerosol-generating article 40 comprises the first electrode 15 and the second electrode 16, and the aerosol-generating device comprises electrical contact points to contact the first electrode 15 and the second electrode 16 when the aerosol-generating article 40 is received in the article cavity 32. It will also be appreciated that other embodiments are also envisaged in which the aerosol-generating article 40 comprises one of the first electrode 15 and the second electrode 16, and the aerosol-generating device comprises the other one of the first electrode 15 and the second electrode 16, the aerosol-generating device also including an electrical contact point to contact the electrode on the aerosol-generating article 40 when the aerosol-generating article 40 is received in the article cavity 32.

FIG. 7 is a schematic illustration of a shisha system according to an embodiment of this disclosure. The shisha system comprises a shisha device 50 and an aerosol-forming substrate (not shown).

The shisha device 50 comprises a vessel 52 defining a liquid cavity 54. The vessel 52 is configured to retain a volume of liquid in the liquid cavity 54, and is formed from a rigid, optically transparent material, such as glass. In this embodiment, the vessel 52 has a substantially frustoconical shape, and is supported in use at its wide end on a flat, horizontal surface, such as a table or shelf. The liquid cavity 54 is divided into two sections, a liquid section 56 for receiving a volume of liquid, and a headspace 58 above the liquid section 58. A liquid fill level 60 is positioned at the boundary between the liquid section 56 and the headspace 58, the liquid fill level 60 being demarcated on the vessel 52 by a dashed line marked on an outer surface of the vessel 52. A headspace outlet 62 is provided on a side wall of the vessel 52, above the liquid fill level 60. The headspace outlet 62 enables fluid to be drawn out of the liquid cavity 54 from the headspace 58. A mouthpiece 64 is connected to the headspace outlet 62 by a flexible hose 66. A user may draw on the mouthpiece 64 to draw fluid out of the headspace 58 for inhalation.

The shisha device 50 further comprises a heating unit 70 comprising a power supply, a DC/AC converter, an oscillator circuit, a controller, and a capacitor comprising a first electrode, a second electrode and an aerosol-forming substrate in accordance with the present disclosure. Examples of different heating units will be discussed in more detail below with reference to FIGS. 8 and 9. The heating unit 70 is arranged above the vessel 52 by an airflow conduit 72. In this embodiment, the heating unit 70 is supported above the vessel 52 by the airflow conduit 72, however, it will be appreciated that in other embodiments the heating unit 70 may be supported above the vessel 52 by a housing of the shisha device or another suitable support. The airflow conduit 72 extends from the heating unit 70 into the liquid cavity 54 of the vessel 52. The airflow conduit 72 extends through the headspace 58, and below the liquid fill level 60 into the liquid section 58. The airflow conduit 72 comprises an outlet 74 in the liquid section 56 of the liquid cavity 54, below the liquid fill level 60. This arrangement enables air to be drawn from the heating unit 70 to the mouthpiece 64. Air may be drawn from an environment external to the device 50, into the heating unit 70, through the heating unit 70, though the airflow conduit 72 into the volume of liquid in the liquid section 56 of the liquid cavity 54, out of the volume of liquid into the headspace 58, and out of the vessel from the headspace 58 at the headspace outlet 62, through the hose 66 and to the mouthpiece 64.

In use, a user may draw on the mouthpiece 64 of the shisha device 50 to receive aerosol from the shisha device 50. In more detail, an aerosol-generating article comprising an aerosol-forming substrate can be positioned in an article cavity within the heating unit 70 of the shisha device 50. The heating unit 70 may be operated to heat the aerosol-forming substrate within the aerosol-generating article and release volatile compounds from the heated aerosol-forming substrate. When a user draws on the mouthpiece 64 of the shisha device 50, the pressure within the shisha device 50 is lowered, which draws the released volatile compounds from the aerosol-forming substrate out of the heating unit 70 and into the airflow conduit 72. The volatile compounds are drawn out of the airflow conduit 72 at the outlet 74, into the volume of liquid in the liquid section 56 of the liquid cavity 54. The volatile compounds cool in the volume of liquid and are released into the headspace 58 above the liquid fill level 60. The volatile compounds in the headspace 58 condense to form an aerosol that is drawn out of the headspace at the headspace outlet 62 and to the mouthpiece 64 for inhalation by the user.

FIG. 8 shows schematic illustrations of a heating unit 70 of the shisha device 50 of FIG. 7 in combination with an aerosol-generating article 90, forming a shisha system according to an embodiment of this disclosure. FIG. 8a shows the heating unit 70 and the aerosol-generating article 90 before insertion of the aerosol-generating article 90 into an article cavity 14 of the heating unit 70. FIG. 8b shows the aerosol-generating article 90 received in the article cavity 14 of the heating unit 70.

As shown in FIG. 8a, the heating unit 70 comprises an external housing 71. The external housing 71 forms a cylindrical tube that is open at one end for insertion of the aerosol-generating article 90, and is substantially closed at the opposite end. In this embodiment, the external housing 71 is formed from a material that is opaque to RF electromagnetic radiation, such as aluminium. However, it will be appreciated that the housing 71 does not need to be formed from a material that is opaque to RF electromagnetic radiation, but rather in some embodiments may be formed from a material that is substantially transparent to RF electromagnetic radiation, such as a ceramic material or a plastic material.

A closure 75 is moveable over the open end of the external housing 71 of the heating unit 70 to substantially close the open end. In this position, the external housing 71 and the closure 75 define a heating unit cavity. The closure 75 comprises an external housing similar to the external housing 71 of the heating unit, formed from the same material opaque to the RF electromagnetic field and sized and shaped to align and engage with the external housing 71 to close the open end. The closure 75 is rotatably connected to the external housing 71 by a hinge, and is rotatable between an open position, as shown in FIG. 8a, and a closed position, as shown in FIG. 8b. When the closure 75 is in the open position, the open end of the external housing 71 is open for insertion of an aerosol-generating article 90 into the heating unit cavity, and for removal of the aerosol-generating article 90 from the heating unit cavity. When the closure 75 is in the closed position, the heating unit cavity is surrounded by material that is opaque to a RF electromagnetic field, such that a RF electromagnetic field is unable to propagate from the heating unit cavity.

A side wall of the external housing 71 comprises an air inlet (shown in FIG. 8b), for enabling ingress of ambient air into the heating unit cavity.

The heating unit 70 is arranged above the vessel 52 of the shisha device 50 on the airflow conduit 72. The airflow conduit 72 extends into the heating unit cavity and is fixedly attached to the substantially closed end of the external housing 71 of the heating unit 70. It will be appreciated that in other embodiments, the heating unit 70 may be removably attached to the airflow conduit 72, such that the heating unit 70 may be removed for cleaning or replacement if necessary. An opening 73 is provided in the substantially closed end of the external housing 71 to fluidly connect the resonating cavity 80 to the airflow conduit 72.

An article cavity 14 is defined within the heating unit cavity, for receiving the aerosol-generating article 90. The article cavity 14 is defined by a first electrode 15, a second electrode 16, opposite the first electrode 15, and a side wall 76 extending between the first electrode 15 and the second electrode 16. The article cavity 14 is configured to receive the aerosol-generating article 90, and has a shape and size that is complementary to the aerosol-generating article 90. The first electrode 15 and the second electrode 16 are substantially identical planar electrodes with a substantially circular shape. The first electrode 15 is secured to an inner surface of the closure 15, such that the first electrode 15 moves with the closure 75, and the second electrode 16 and side wall 76 are supported in the heating unit cavity by the airflow conduit 72. The second electrode 16 forms a base of the article cavity 14, the side wall 76 forms a side wall of the article cavity 14, and the first electrode 15 forms a top wall of the article cavity 14 when the closure 75 is in the closed position. The side wall 76 is formed from an electrically insulative material, in this embodiment a ceramic material, such as PEEK. Accordingly, the side wall 76 ensures that the first electrode 15 and the second electrode 16 do not come into electrical contact with each other.

The side wall 76 of the article cavity 14 is gas permeable, having slots formed therein to enable air to flow through the article cavity 14, from one side to the other, as shown in FIG. 8b. Accordingly, the heating unit 70 is configured such that air may be drawn into the heating unit cavity through the air inlet, through the article cavity 14 through the slots in the side wall 76 of the article cavity 14, and from the heating unit cavity into the airflow conduit 72, through the opening 73.

In the embodiment of FIG. 8 the side wall 76 of the article cavity 14 is gas permeable to enable air to flow out of the article cavity 14; however, it will be appreciated that in other embodiment one or both of the first electrode 15 and the second electrode 16 may be gas permeable to enable air to flow out of the article cavity 14.

The heating unit 70 further comprises an oscillation circuit 10. The oscillation circuit 10 is connected to a power supply (not shown) and a controller (not shown) of the shisha device, the controller being configured to control the supply of power from the power supply to the oscillation circuit 10. In this embodiment, the power supply is a rechargeable lithium ion battery, and the shisha device 50 comprises a power connector that enables the shisha device 50 to be connected to a mains power supply for recharging the power supply. Providing the shisha device 50 with a power supply, such as a battery, enables the shisha device 50 to be portable and used outdoors or in locations in which a mains power supply is not available.

The first electrode 15 is electrically connected to the oscillation circuit 10 by a flexible circuit. The second electrode 16 is also electrically connected to the oscillation circuit 10.

The aerosol-generating article 90 comprises an aerosol-forming substrate 92. In this embodiment, the aerosol-forming substrate 92 is a shisha substrate, comprising molasses and tobacco. The aerosol-forming substrate 92 is encased within a wrapper 94, formed from a gas permeable, electrically insulating material, such as tipping paper. The aerosol-generating article 90 has a substantially cylindrical shape, similar to a hockey puck, which is complimentary to the shape of the article cavity 14 of the shisha device 50.

As shown in FIG. 8b, when the aerosol-generating article 90 is received in the article cavity 14 of the heating unit 70, a circular base of the aerosol-generating article 90 contacts the second electrode 16 of the article cavity 14, and the sides of the aerosol-generating article 90 contact the side wall 76 of the article cavity 14. When the closure 75 is arranged in the closed position, the circular top of the aerosol-generating article 90 contacts the first electrode 15 of the article cavity 14. In this arrangement, the first electrode 15, second electrode 16 and aerosol-generating article 90 form a capacitor, with the aerosol-forming substrate 90 defining the dielectric material between the first electrode 15 and the second electrode 16.

When a user draws on the mouthpiece 64 of the shisha device 50, air is drawn into the shisha device 50 through the air inlet of the external housing 71. An airflow path through the aerosol-generating article 90 and heating unit 70 is shown by the arrows in FIG. 8b. Air is drawn into the heating unit cavity through the air inlet of the external housing 71, and from the heating unit cavity into the aerosol-generating article 90 through the side wall 76 of the article cavity 14. Air is drawn through the aerosol-forming substrate 92 and back into the heating unit cavity through an opposite portion of the side wall 76 of the article cavity 14, and from the heating unit cavity into the airflow conduit 72 through the opening 73 in the external housing 71 of the heating unit 70.

In use, power is supplied to the oscillation circuit 10 from the power supply when a user activates the shisha device 50. In this embodiment, the shisha device is activated by a user pressing an activation button (not shown) provided on an external surface of the heating unit 70. It will be appreciated that in other embodiments, the shisha device may be activated in another manner, such as on detection of a user drawing on the mouthpiece 64 by a puff sensor provided on the mouthpiece 64. When power is supplied to the oscillation circuit 10, the oscillation circuit generates two substantially equal, out of phase RF electromagnetic signals with a frequency of between 1 Hz and 300 MHz. One of the signals is supplied to the first electrode 15, and the other signal is supplied to the second electrode 16.

The RF electromagnetic signals supplied to the first electrode 15 and the second electrode 16 establish an alternating RF electromagnetic field in the article cavity 14, which dielectrically heats the aerosol-forming substrate 90, which releases volatile compounds. As described above, the temperature in the article cavity 14 is regulated using a feedback control mechanism. The temperature of the aerosol-forming substrate is determined based on a measured electrical property between the first electrode 15 and the second electrode 16, to provide a feedback signal to the control circuitry of the shisha device 50. The control circuitry is configured to adjust the frequency or amplitude, or both the frequency and the amplitude, of the RF electromagnetic field based on the measured electrical property in order to maintain the temperature inside the article cavity 14 within a desired temperature range.

When a user draws on the mouthpiece 64 of the shisha device 50, the volatile compounds released from the heated aerosol-forming substrate 90 are entrained in the airflow through the aerosol-generating article 90 and are drawn out of the aerosol-generating article 90, through the heating unit 70 and into the airflow conduit 72 through the opening 73. From the airflow conduit 72, the volatile compounds are drawn through the shisha device 50 to and out of the mouthpiece 66 as described above.

FIG. 9 shows a heating unit 70 for a shisha device and an aerosol-generating article 90, forming a shisha system according to another embodiment of this disclosure. The heating unit 70 and aerosol-generating article 90 shown in FIG. 9 are substantially similar to the heating unit 70 and aerosol-generating article 90 shown in FIG. 8, and like reference numerals are used to represent like features. FIG. 9a shows the heating unit 70 and the aerosol-generating article 90 before insertion of the aerosol-generating article 90 into an article cavity 14 of the heating unit 70. FIG. 9b shows the aerosol-generating article 90 received in the article cavity 14 of the heating unit 70.

The heating unit 70 shown in FIG. 9 differs from the heating unit 70 shown in FIG. 8 in that the first electrode 15 comprises an elongate, cylindrical electrode, and the second electrode 16 comprises an elongate, tubular electrode that circumscribes the first electrode 15.

The article cavity 14 is defined between the first electrode 15, the second electrode 16, and a base 78, forming an elongate annular cavity that is open at one end and substantially closed at the opposite end. The base 78 is formed from an electrically insulating material, such as PEEK, and comprises a plurality of slots to enable air to flow out of the article cavity 14. The base 78 is supported above a flared end of the airflow conduit 72, such that air flowing out of the article cavity 14 flows into the airflow conduit 72, as shown in FIG. 9b. In some embodiments, the flared end of the airflow conduit 72 is an integral part of the airflow conduit 72, however, in this embodiment, the flared end of the airflow conduit 72 is an integral part of the heating unit 70, and is removable from the airflow conduit with the heating unit 70.

In the embodiment of FIG. 9 a plurality of slots are formed in the electrically insulating material of the base 78 to enable air to flow out of the article cavity 14; however, it will be appreciated that in other embodiment a plurality of slots may be formed in one or both of the first electrode 15 and the second electrode 16 to enable air to flow out of the article cavity 14.

The heating unit 70 shown in FIG. 9 also differs from the heating unit 70 shown in FIG. 8 in that the external housing 71 does not comprises a closure, but rather the article cavity 14 comprises a closure 80, which is hingedly mounted to the second electrode 16. The closure 80 is movable between an open position, as shown in FIG. 9a, to enable the aerosol-generating article to be inserted in the article cavity 14, and a closed position, as shown in FIG. 9b, for closing the open end of the article cavity 14. The closure 80 is similar to the base 78, in that it is formed from an electrically insulative material, such as PEEK, and comprises a plurality of slots to enable air to enter the article cavity 14 when the closure 80 is in the closed position. The closure 80 further comprises an electrical contact 82, centrally positioned on the closure, for contact with the first electrode 15 when the closure 80 is in the closed position, electrically connecting the first electrode 15 to the oscillation circuit 10. The electrical contact 82 is electrically connected to the oscillation circuit via a flexible circuit. The outer surface of the second electrode 16 is also electrically connected to the oscillation circuit 10.

In this embodiment, the aerosol-generating article 90 has an elongate, tubular shape that is complementary to the shape of the article cavity 14. In particular, the aerosol-forming substrate 92 comprises an inner passage 97 that is complementary in size and shape to the first electrode 15. When the aerosol-generating article 90 is received in the article cavity 14, the inner surface of the inner passage 97 of the aerosol-generating article 90 contacts the outer surface of the first electrode 15, and the outer surface of the aerosol-generating article 90 contacts the inner surface of the second electrode 16.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A±5% of A.

1.-15. (canceled)

16. An aerosol-generating system, comprising:
an aerosol-forming substrate;
a first electrode and a second electrode spaced apart from the first electrode;
an aerosol-generating device comprising:
a power supply, and
a controller configured to connect to the first electrode and the second electrode; and
a capacitor comprising the first electrode, the second electrode, and at least a portion of the aerosol-forming substrate,
wherein the controller is configured to:
supply an alternating voltage to the first electrode and the second electrode for dielectrically heating the aerosol-forming substrate,
measure or determine an electrical property between the first electrode and the second electrode, and
control heating of the aerosol-forming substrate based on the measured or determined electrical property.

17. The aerosol-generating system according to claim 16, wherein the controller is further configured to supply an alternating voltage to the first electrode and the second electrode for measuring or determining the electrical property between the first electrode and the second electrode.

18. The aerosol-generating system according to claim 16, wherein the controller is further configured to determine an impedance between the first electrode and the second electrode.

19. The aerosol-generating system according to claim 17, wherein the controller is further configured to measure an alternating electrical current supplied to the first electrode and the second electrode when the alternating voltage for measuring or determining the electrical property between the first electrode and the second electrode is supplied.

20. The aerosol-generating system according to claim 19, wherein the controller is further configured to control heating of a portion of the aerosol-forming substrate based on the measured alternating current.

21. The aerosol-generating system according to claim 19,
wherein the controller is further configured to determine an impedance between the first electrode and the second electrode based on the measured alternating current, and
wherein the controller is further configured to control heating of the aerosol-forming substrate based on the determined impedance.

22. The aerosol-generating system according to claim 16,
wherein the power supply is configured to supply a direct voltage,
wherein a DC/AC converter is arranged at an output of the power supply for supplying an alternating voltage to the first electrode and the second electrode,
wherein the controller is further configured to control a supply of the alternating voltage from the DC/AC converter to the first electrode and the second electrode, and
wherein the controller is further configured to measure a direct electrical current supplied to the DC/AC converter.

23. The aerosol-generating system according to claim 22, wherein the controller is further configured to control heating of the aerosol-forming substrate based on the measured direct current.

24. The aerosol-generating system according to claim 22,
wherein the controller is further configured to determine an impedance between the first electrode and the second electrode based on the measured direct current, and
wherein the controller is further configured to control heating of the aerosol-forming substrate based on the determined impedance.

25. The aerosol-generating system according to claim 16,
wherein a portion of the aerosol-forming substrate is removably receivable between the first electrode and the second electrode, and
wherein the controller is further configured to determine whether aerosol-forming substrate is received between the first electrode and the second electrode based on the measured or determined electrical property between the first electrode and the second electrode.

26. The aerosol-generating system according to claim 25, wherein the controller is further configured to prevent heating of the aerosol-forming substrate when it is determined that aerosol-forming substrate is not received between the first electrode and the second electrode.

27. The aerosol-generating system according to claim 16, wherein the controller is further configured to determine a temperature of the aerosol-forming substrate based on the measured or determined electrical property between the first electrode and the second electrode.

28. The aerosol-generating system according to claim 27, wherein the controller is further configured to determine a physical characteristic of the aerosol-forming substrate based on the measured or determined electrical property.

29. The aerosol-generating system according to claim 16,
wherein the aerosol-forming substrate is removably receivable between the first electrode and the second electrode, and
wherein the controller is further configured to determine whether the aerosol-forming substrate received between the first electrode and the second electrode is authentic based on the measured or determined electrical property.

30. The aerosol-generating system according to claim 29, wherein the controller is further configured to prevent heating of the aerosol-forming substrate when it is determined that the aerosol-forming substrate received between the first electrode and the second electrode is not authentic.

31. The aerosol-generating system according to claim 16,
wherein an inductor is arranged between the power supply and the capacitor comprising the first electrode, the second electrode, and at least a portion of the aerosol-forming substrate,
wherein the inductor and the capacitor comprising the first electrode, the second electrode, and at least a portion of the aerosol-forming substrate form a resonant circuit having a resonant frequency, and
wherein the resonant frequency is dependent on the measured or determined electrical property between the first electrode and the second electrode, and/or
wherein the aerosol-generating device further comprises the first electrode and the second electrode.

32. The aerosol-generating system according to claim 16,
further comprising an aerosol-generating article comprising the aerosol-forming substrate,
wherein either:
the aerosol-generating article further comprises the first electrode and the second electrode, or
the aerosol-generating device further comprises one of the first electrode and the second electrode, and the aerosol-generating article further comprises the other one of the first electrode and the second electrode.

33. An aerosol-generating device for dielectrically heating an aerosol-forming substrate, the aerosol-generating device comprising:
a first electrode and a second electrode spaced apart from the first electrode;
a power supply; and
a controller configured to connect to the first electrode and the second electrode,
wherein the first electrode and the second electrode are configured to form a capacitor with a portion of the aerosol-forming substrate to be dielectrically heated, and
wherein the controller is further configured to:
supply an alternating voltage to the first electrode and the second electrode for dielectrically heating a portion of the aerosol-forming substrate,
measure or determine an electrical property between the first electrode and the second electrode, and
control heating of the aerosol-forming substrate based on the determined electrical property.
